(19) United States
(12) Patent Application Publication
(10) Pub. No.: US 2015/0309085 A1
(43) Pub. Date: Oct. 29, 2015

(54) CALCULATING LINE-TO-NEUTRAL VOLTAGES WITHOUT A CONNECTION TO A SYSTEM NEUTRAL OR EARTH GROUND

(71) Applicant: Rockwell Automation Technologies, Inc., Mayfield Heights, OH (US)

(72) Inventors: Douglas Fieldbinder, Franklin, WI (US); Eric Waydick, Saint Francis, WI (US); Issa V. Drame, West Allis, WI (US)

(73) Assignee: Rockwell Automation Technologies, Inc., Mayfield Heights, OH (US)

(21) Appl. No.: 14/263,565

(22) Filed: Apr. 28, 2014

(51) Int. Cl. G01R 19/00

(52) U.S. Cl. CPC G01R 19/0084

(57) ABSTRACT

A method measures three line-to-line voltages and constructs a phasor triangle with the voltages phasors. V_{ab} extends from a first point horizontally to the origin. V_{bc} extends between the origin and a second point. V_{ca} extends between the second point and the first point. The method includes adding a first line segment that extends from a point that bisects V_{bc} in a direction perpendicular to V_{bc} to a third point. The method adds a second line segment from a point that bisects V_{ca} in a direction perpendicular to V_{ca} to a fourth point. The method adds a third line segment from the third point to the first point and a fourth line segment from the fourth point to the origin. The third line segment intersects the fourth line segment at a neutral point. A line-to-neutral voltage is a line from the neutral point to a vertex of the phasor triangle.

### CROSS-REFERENCE TO RELATED APPLICATIONS

1. Field

The subject matter disclosed herein relates to calculating voltage and more particularly relates to calculating line-to-neutral voltage without a connection to a system neutral or earth ground.

2. Background Information

Typical three-phase systems include three alternating current (“AC”) voltages that have a fundamental frequency, such a 50 hertz (“Hz”), 60 Hz, 400 Hz, etc. that are offset in time so that the three phases are spaced 120 degrees within one cycle. A three-phase power system can supply power to three-phase loads as well as single-phase loads. Many three-phase loads, such as motors are balanced loads under normal operating conditions and do not require a neutral connection. Other loads may also not require a neutral connection, such as the primary side of a transformer in a delta-wye or delta-delta configuration. Measurement of voltages within a three-phase power system can be important for a variety of reasons, such as power quality monitoring, overcurrent protection, power monitoring, etc.

Some three-phase power systems have neutral connections available for some loads while other three-phase loads do not have a neutral connection available. Often power systems have a connection between the neutral, which is also called the grounded conductor, and a system ground, such as earth ground or a ground to a structure. For safety reasons, a grounding conductor, which is usually marked green or is bare copper, is run with power conductors to a load. This grounding conductor may be called a safety ground and typically connects to structures and frames of equipment being powered in the three-phase power system to provide a low impedance path for fault current. The safety ground is often nearly the same potential as the neutral, however, when current flows in the neutral, voltage drop from the load to the neutral to ground connection, which is usually at a three-phase power source for a system, can be substantial. In fault conditions, at a load voltage between a neutral and a safety ground can vary significantly so determining line-to-neutral voltage by simply measuring line-to-ground can be inaccurate, especially under fault conditions.

Some three-phase power systems are isolated from a grounded structure. For example, some three-phase power systems in marine vessels are isolated from the grounded structure of the vessel. For loads in such an ungrounded system that do not have a neutral available, line-to-neutral voltage measurements are not available. Having a line-to-neutral voltage available for loads with no available neutral connection and for three-phase power systems that are floating is desirable for a variety of reasons.

### BRIEF DESCRIPTION

A method for determining voltage is disclosed. An apparatus and computer program product also perform the functions of the method. The method for determining voltage includes measuring three line-to-line voltages for the phases in a three-phase power system, where each line-to-line voltage includes a voltage magnitude, and constructing, on a two-dimensional coordinate system with an origin, a phasor triangle that includes the three line-to-line voltages represented as phasors. A first phasor V_{ab} originates at a first point and extends in a direction along a horizontal axis of the coordinate system to the origin and a second phasor V_{bc} extends between the origin and a second point. The second point is in a direction vertically and horizontally from the origin. A third phasor V_{ca} extends between the second point and the first point.

The method, in one embodiment, includes adding a first line segment that extends from a point that bisects the second phasor V_{bc} in a direction perpendicular to the second phasor V_{bc} and away from the phasor triangle. The first line segment terminates at a third point. The method, in another embodiment, includes adding a second line segment that extends from a point that bisects the third phasor V_{ca} in a direction perpendicular to the third phasor V_{ca} and away from the phasor triangle. The second line segment terminates at a fourth point. In one embodiment, the method includes adding a third line segment from the third point to the first point and adding a fourth line segment from the fourth point to the origin, where the third line segment intersects the fourth line segment at a neutral point. The method, in another embodiment, includes determining a line-to-neutral voltage. The line-to-neutral voltage includes a line from the neutral point to a vertex of the phasor triangle.

In one embodiment, determining a line-to-neutral voltage may include determining a line-to-neutral voltage for a phasor Vₐₙ for phase A which includes determining a line from the neutral point to the first point, determining a line-to-neutral voltage for a phasor V_{bn} for phase B which includes determining a line from the neutral point to the origin, and/or determining a line-to-neutral voltage for a phasor V_{cn} for phase C which includes determining a line from the neutral point to the second point. In another embodiment, the method includes determining a magnitude of phasor Vₐₙ as

Vₐₙ=\sqrt{(xₐ−xₙ)²+(yₐ−yₙ)²};

determining a magnitude of phasor V_{bn} as

V_{bn}=\sqrt{(x_{b}−xₙ)²+(y_{b}−yₙ)²}; and

determining a magnitude of phasor V_{cn} as

V_{cn}=\sqrt{(x_{c}−xₙ)²+(y_{c}−yₙ)²}.

In one embodiment, the first point has a coordinate of (xₐ, yₐ), the second point has a coordinate of (x_{c}, y_{c}), and the origin has a coordinate of (x_{b}, y_{b}) and xₐ=the magnitude of the V_{ab} phasor and yₐ=0, x_{b}=0 and

$${y}_{b} = 0 , \\ {x}_{c} = \frac{{V}_{ab}^{2} - {V}_{ca}^{2} + {V}_{bc}^{2}}{2 \cdot {V}_{ab}}$$

and

$${y}_{c} = {V}_{ca} \cdot \sqrt{1 - ( \frac{{V}_{bc}^{2} - {V}_{ab}^{2} - {V}_{ca}^{2}}{4 \cdot {V}_{ab}^{2} \cdot {V}_{ca}^{2}} )} ,$$

where V_{ab} is a magnitude of the first phasor V_{ab}, V_{bc} is a magnitude of the second phasor V_{bc}, and V_{ca} is a magnitude of the third phasor V_{ca}. In one embodiment, the length of the first line segment has a magnitude of the third phasor V_{ca} divided by the square root of three and multiplied by the square root of one plus the square of the slope of the first line segment and the length of the second line segment has a magnitude of the second phasor V_{bc} divided by the square root of three and multiplied by the square root of one plus the square of the slope of the second line segment.

In another embodiment, the length of the first line segment is:

$$\frac{{V}_{ca}}{\sqrt{3}} \cdot \sqrt{1 + {( \frac{- {x}_{c}}{{y}_{c}} )}^{2}}$$

and the length of the second line segment is

$$\frac{{V}_{bc}}{\sqrt{3}} \cdot \sqrt{1 + {( \frac{- ( {x}_{a} - {x}_{c} )}{( {y}_{a} - {y}_{c} )} )}^{2}} .$$

In one embodiment, the third point has a coordinate of (x_{pbc}, y_{pbc}) and the fourth point has a coordinate of (x_{pca}, y_{pca}), where

$${x}_{pbc} = \frac{{x}_{c}}{2} - \frac{{V}_{ca}}{\sqrt{3}} ;$$

$${y}_{pbc} = \frac{{y}_{c}}{2} - \frac{- {x}_{c}}{{y}_{c}} \cdot \frac{{V}_{ca}}{\sqrt{3}} ;$$

$${x}_{pca} = {x}_{c} + \frac{{x}_{a} - {x}_{c}}{2} + \frac{{V}_{bc}}{\sqrt{3}} ; and$$

$${y}_{pca} = \frac{{y}_{c}}{2} + \frac{- ( {x}_{a} - {x}_{c} )}{( {y}_{a} - {y}_{c} )} \cdot \frac{{V}_{bc}}{\sqrt{3}} .$$

In another embodiment, the neutral point has a coordinate of (xₙ, yₙ), where:

$${x}_{n} = \frac{\frac{{y}_{pbc}}{{x}_{a} - {x}_{pbc}} \cdot {x}_{a}}{\frac{{y}_{pca}}{{x}_{pca}} + \frac{{y}_{pbc}}{{x}_{a} - {x}_{pbc}}} ; and$$

$${y}_{n} = \frac{{y}_{pca}}{{x}_{pca}} \cdot {x}_{n} .$$

In another embodiment, where yₙ is less than zero then yₙ=0, and where yₙ is greater than or equal to zero and greater than y_{c} then yₙ=y_{c}. In another embodiment, where xₙ is less than zero then xₙ=0, and where xₙ is greater than or equal to zero and greater than xₐ then xₙ=xₐ, and where xₙ is greater than or equal to zero and less than or equal to xₐ and y_{c}=yₙ then xₙ=x_{c}.

In one embodiment, the length of the first line segment has a magnitude of the second phasor V_{bc} multiplied by the square root of three and divided by two, which represents a height of a first equilateral triangle constructed on the second phasor V_{bc} and extending away from the phasor triangle and the length of the second line segment has a magnitude of the third phasor V_{ca} multiplied by the square root of three and divided by two, which represents a height of a second equilateral triangle constructed on the third phasor V_{ca} and extending away from the phasor triangle. In another embodiment, the third point has a coordinate of (x_{pbc}, y_{pbc}) and the fourth point has a coordinate of (x_{pca}, y_{pca}), where:

$${x}_{pbc} = \frac{{x}_{c} - {y}_{c} \cdot \sqrt{3}}{2} ;$$

$${y}_{pbc} = \frac{{y}_{c} + {x}_{c} \cdot \sqrt{3}}{2} ;$$

$${x}_{pca} = {x}_{a} + \frac{{x}_{c} - {x}_{a} + \sqrt{3} \cdot {y}_{c}}{2} ; and$$

$${y}_{pca} = \frac{( {y}_{c} - {y}_{a} ) + \sqrt{3} \cdot ( {x}_{a} - {x}_{c} )}{2} .$$

In another embodiment, the neutral point has a coordinate of (xₙ, yₙ) where:

$${x}_{n} = \frac{\frac{{x}_{a} \cdot {y}_{pbc}}{{x}_{a} - {x}_{pbc}}}{\frac{{y}_{pca}}{{x}_{pca}} + \frac{{y}_{pbc}}{{x}_{a} - {x}_{pbc}}} ; and$$

$${y}_{n} = \frac{{y}_{pca}}{{x}_{pca}} \cdot {x}_{n} .$$

In one embodiment, the line-to-line voltages are measured at a location in the three-phase power system where a neutral connection is unavailable for measurement. In another embodiment, the three-phase power system includes an ungrounded power system. In another embodiment, the three-phase power system includes unbalanced voltages. In another embodiment, the first phasor V_{ab}, the second phasor V_{bc}, and the third phasor V_{ca} are separated by 120 degrees.

An apparatus for determining voltages, in one embodiment, includes a measurement module that measures three line-to-line voltages for the phases in a three-phase power system, where each line-to-line voltage includes a voltage magnitude. The apparatus, in one embodiment, includes a triangle module that constructs, on a two-dimensional coordinate system with an origin, a phasor triangle with the three line-to-line voltages represented as phasors, where a first phasor V_{ab} originates at a first point and extends in a direction along a horizontal axis of the coordinate system to the origin, a second phasor V_{bc} extends between the origin and a second point, the second point in a direction vertically and horizontally from the origin, and a third phasor V_{ca} extends between the second point and the first point.

The apparatus, in one embodiment, includes a first line module that adds a first line segment that extends from a point that bisects the second phasor V_{bc} in a direction perpendicular to the second phasor V_{bc} and away from the phasor triangle. The first line segment terminates at a third point. In another embodiment, the apparatus includes a second line module that adds a second line segment that extends from a point that bisects the third phasor V_{ca} in a direction perpendicular to the third phasor V_{ca} and away from the phasor triangle. The second line segment terminates at a fourth point. The apparatus, in one embodiment, includes a third line module that adds a third line segment from the third point to the first point and a fourth line module that adds a fourth line segment from the fourth point to the origin, where the third line segment intersects the fourth line segment at a neutral point. The apparatus, in another embodiment, includes a line-to-neutral module that determines a line-to-neutral voltage. The line-to-neutral voltage includes a line from the neutral point to a vertex of the phasor triangle.

In one embodiment, the line-to-neutral module determines a line-to-neutral voltage by determining a line-to-neutral voltage for phasor Vₐₙ for phase A which includes determining a line from the neutral point to the first point. In another embodiment, the line-to-neutral module determines a line-to-neutral voltage by determining a line-to-neutral voltage for phasor V_{bn} for phase B which includes determining a line from the neutral point to the origin. In another embodiment, the line-to-neutral module determines a line-to-neutral voltage by determining a line-to-neutral voltage for phasor V_{cn} for phase C which comprises determining a line from the neutral point to the second point. For example, the apparatus may include a line-to-neutral magnitude module that determines a magnitude of phasor Vₐₙ as

Vₐₙ=\sqrt{(xₐ−xₙ)²+(yₐ−yₙ)²},

determines a magnitude of phasor V_{bn} as

V_{bn}=\sqrt{(x_{b}−xₙ)²+(y_{b}−yₙ)²}, and/or

determines a magnitude of phasor V_{cn} as

V_{cn}=\sqrt{(x_{c}−xₙ)²+(y_{c}−yₙ)²}.

In one embodiment, first point has a coordinate of (xₐ, yₐ), the second point has a coordinate of (x_{c}, y_{c}), and the origin has a coordinate of (x_{b}, y_{b}) where xₐ=the magnitude of the V_{ab} phasor and yₐ=0, x_{b}=0 and y_{b}=0, and

$${x}_{c} = \frac{{V}_{ab}^{2} - {V}_{ca}^{2} + {V}_{bc}^{2}}{2 \cdot {V}_{ab}}$$

$$and$$

$${y}_{c} = {V}_{ca} \cdot \sqrt{1 - ( \frac{{V}_{bc}^{2} - {V}_{ab}^{2} - {V}_{ca}^{2}}{4 \cdot {V}_{ab}^{2} \cdot {V}_{ca}^{2}} )} .$$

V_{ab} is a magnitude of the first phasor V_{ab}, V_{bc} is a magnitude of the second phasor V_{bc}, and V_{ca} is a magnitude of the third phasor V_{ca}.

In one embodiment, the length of the first line segment has a magnitude of the third phasor V_{ca} divided by the square root of three and multiplied by the square root of one plus the square of the slope of the first line segment and the length of the second line segment has a magnitude of the second phasor V_{bc} divided by the square root of three and multiplied by the square root of one plus the square of the slope of the second line segment.

In another embodiment, the third point has a coordinate of (x_{pbc}, y_{pbc}) and the fourth point has a coordinate of (x_{pca}, y_{pca}), where

$${x}_{pbc} = \frac{{x}_{c}}{2} - \frac{{V}_{ca}}{\sqrt{3}} ;$$

$${y}_{pbc} = \frac{{y}_{c}}{2} - \frac{- {x}_{c}}{{y}_{c}} \cdot \frac{{V}_{ca}}{\sqrt{3}} ;$$

$${x}_{pca} = {x}_{c} + \frac{{x}_{a} - {x}_{c}}{2} + \frac{{V}_{bc}}{\sqrt{3}} ; and$$

$${y}_{pca} = \frac{{y}_{c}}{2} + \frac{- ( {x}_{a} - {x}_{c} )}{( {y}_{a} - {y}_{c} )} \cdot \frac{{V}_{bc}}{\sqrt{3}} .$$

In one embodiment, the neutral point has a coordinate of (xₙ, yₙ), where:

$${x}_{n} = \frac{\frac{{y}_{pbc}}{{x}_{a} - {x}_{pbc}} \cdot {x}_{a}}{\frac{{y}_{pca}}{{x}_{pca}} + \frac{{y}_{pbc}}{{x}_{a} - {x}_{pbc}}} ; and$$

$${y}_{n} = \frac{{y}_{pca}}{{x}_{pca}} \cdot {x}_{n} .$$

In one embodiment, where yₙ is less than zero then yₙ=0, and where yₙ is greater than or equal to zero and greater than y_{c} then yₙ=y_{c}. In another embodiment, where xₙ is less than zero then xₙ=0, and where xₙ is greater than or equal to zero and greater than xₐ then xₙ=xₐ, and where xₙ is greater than or equal to zero and less than or equal to xₐ and y_{c}=yₙ then xₙ=x_{c}.

In one embodiment, the length of the first line segment has a magnitude of the second phasor V_{bc} multiplied by the square root of three and divided by two, which represents a height of a first equilateral triangle constructed on the second phasor V_{bc} and extending away from the phasor triangle and the length of the second line segment has a magnitude of the third phasor V_{ca} multiplied by the square root of three and divided by two, which represents a height of a second equilateral triangle constructed on the third phasor V_{ca} and extending away from the phasor triangle. For example, the third point may have a coordinate of (x_{pbc}, y_{pbc}) and the fourth point may have a coordinate of (x_{pca}, y_{pca}) where:

$${x}_{pbc} = \frac{{x}_{c} - {y}_{c} \cdot \sqrt{3}}{2} ;$$

$${y}_{pbc} = \frac{{y}_{c} + {x}_{c} \cdot \sqrt{3}}{2} ;$$

$${x}_{pca} = {x}_{a} + \frac{{x}_{c} - {x}_{a} + \sqrt{3} \cdot {y}_{c}}{2} ; and$$

$${y}_{pca} = \frac{( {y}_{c} - {y}_{a} ) + \sqrt{3} \cdot ( {x}_{a} - {x}_{c} )}{2} .$$

In one embodiment, the neutral point has a coordinate of (xₙ, yₙ) and where:

$${x}_{n} = \frac{\frac{{x}_{a} \cdot {y}_{pbc}}{{x}_{a} - {x}_{pbc}}}{\frac{{y}_{pca}}{{x}_{pca}} + \frac{{y}_{pbc}}{{x}_{a} - {x}_{pbc}}} ; and$$

$${y}_{n} = \frac{{y}_{pca}}{{x}_{pca}} \cdot {x}_{n} .$$

In another embodiment, the apparatus includes a meter where the meter includes the measurement module. In another embodiment, the apparatus includes a processor that executes executable code of the measurement module, the triangle module, the first line module, the second line module, the third line module, the fourth line module, and/or the line-to-neutral module.

A computer program product for determining a voltage is included. The computer program product includes a computer readable storage medium having program code embodied therein. The program code is readable/executable by a processor for measuring three line-to-line voltages for the phases in a three-phase power system, where each line-to-line voltage includes a voltage magnitude, and constructing, on a two-dimensional coordinate system with an origin, a phasor triangle with the three line-to-line voltages represented as phasors. A first phasor V_{ab} originates at a first point and extends in a direction along a horizontal axis of the coordinate system to the origin. A second phasor V_{bc} extends between the origin and a second point, where the second point is in a direction vertically and horizontally from the origin. A third phasor V_{ca} extends between the second point and the first point.

In one embodiment, the program code is readable/executable by a processor for determining a third point by adding a first line segment that extends from a point that bisects the second phasor V_{bc} in a direction perpendicular to the second phasor V_{bc} and away from the phasor triangle. The first line segment terminates at the third point. In another embodiment, the program code is readable/executable by a processor for determining a fourth point by adding a second line segment that extends from a point that bisects the third phasor V_{ca} in a direction perpendicular to the third phasor V_{ca} and away from the phasor triangle. The second line segment terminates at the fourth point.

The program code, in one embodiment, is readable/executable by a processor for determining a neutral point by adding a third line segment from the third point to the first point and adding a fourth line segment from the fourth point to the origin, where the third line segment intersects the fourth line segment at the neutral point, and determining a line-to-neutral voltage. The line-to-neutral voltage includes a line from the neutral point to a vertex of the phasor triangle.

### BRIEF DESCRIPTION OF THE DRAWINGS

In order that the advantages of the embodiments of the invention will be readily understood, a more particular description of the embodiments briefly described above will be rendered by reference to specific embodiments that are illustrated in the appended drawings. Understanding that these drawings depict only some embodiments and are not therefore to be considered to be limiting of scope, the embodiments will be described and explained with additional specificity and detail through the use of the accompanying drawings, in which:

FIG. 1 is a schematic block diagram illustrating one embodiment of a system for determining voltages;

FIG. 2 is a schematic block diagram illustrating one embodiment of an apparatus for determining voltages;

FIG. 3 is a diagram of voltages of a three-phase power system with unbalanced voltages;

FIG. 4 is a diagram of voltages of a three-phase power system with unbalanced voltages repositioned as a phasor triangle;

FIG. 5 is a diagram of voltages of the three-phase power system with unbalanced voltages repositioned as a phasor triangle with perpendicular lines bisecting two sides using a first geometric method;

FIG. 6 is a diagram of voltages of the three-phase power system with unbalanced voltages repositioned as a phasor triangle with perpendicular lines bisecting two sides and lines intersecting a neutral point using the first geometric method;

FIG. 7 is a diagram of voltages of the three-phase power system with unbalanced voltages repositioned as a phasor triangle with line-to-neutral phasors shown from the neutral point using the first geometric method;

FIG. 8 is a diagram of voltages of the three-phase power system with unbalanced voltages repositioned as a phasor triangle with perpendicular lines bisecting two sides where the length is based on an equilateral triangle using a second geometric method;

FIG. 9 is a diagram of voltages of the three-phase power system with unbalanced voltages repositioned as a phasor triangle with perpendicular lines bisecting two sides and lines intersecting a neutral point using the second geometric method;

FIG. 10 is a diagram of voltages of the three-phase power system with unbalanced voltages repositioned as a phasor triangle with line-to-neutral phasors shown from the neutral point using the second geometric method;

FIG. 11 is a schematic flow chart diagram illustrating one embodiment of a method for determining voltages;

FIG. 12A is a first part of a schematic flow chart diagram illustrating another embodiment of a method for determining voltages;

FIG. 12B is second part of a schematic flow chart diagram illustrating another embodiment of a method for determining voltages;

FIG. 13 is a plot of laboratory test results showing percent voltage imbalance versus reported voltage error using the first geometric method; and

FIG. 14 is a plot of laboratory test results showing reported voltage error under balanced conditions using the first geometric method.

### DETAILED DESCRIPTION

Reference throughout this specification to “one embodiment,” “an embodiment,” or similar language means that a particular feature, structure, or characteristic described in connection with the embodiment is included in at least one embodiment. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

Furthermore, the described features, advantages, and characteristics of the embodiments may be combined in any suitable manner. One skilled in the relevant art will recognize that the embodiments may be practiced without one or more of the specific features or advantages of a particular embodiment. In other instances, additional features and advantages may be recognized in certain embodiments that may not be present in all embodiments.

These features and advantages of the embodiments will become more fully apparent from the following description and appended claims, or may be learned by the practice of embodiments as set forth hereinafter. As will be appreciated by one skilled in the art, aspects of the present invention may be embodied as a system, method, and/or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module,” or “system.” Furthermore, aspects of the present invention may take the form of a computer program product embodied in one or more computer readable medium(s) having program code embodied thereon.

Many of the functional units described in this specification have been labeled as modules, in order to more particularly emphasize their implementation independence. For example, a module may be implemented as a hardware circuit comprising custom VLSI circuits or gate arrays, off-the-shelf semiconductors such as logic chips, transistors, or other discrete components. A module may also be implemented in programmable hardware devices such as field programmable gate arrays, programmable array logic, programmable logic devices or the like.

Modules may also be implemented in software for execution by various types of processors. An identified module of program code may, for instance, comprise one or more physical or logical blocks of computer instructions which may, for instance, be organized as an object, procedure, or function. Nevertheless, the executables of an identified module need not be physically located together, but may comprise disparate instructions stored in different locations which, when joined logically together, comprise the module and achieve the stated purpose for the module.

Indeed, a module of program code may be a single instruction, or many instructions, and may even be distributed over several different code segments, among different programs, and across several memory devices. Similarly, operational data may be identified and illustrated herein within modules, and may be embodied in any suitable form and organized within any suitable type of data structure. The operational data may be collected as a single data set, or may be distributed over different locations including over different storage devices, and may exist, at least partially, merely as electronic signals on a system or network. Where a module or portions of a module are implemented in software, the program code may be stored and/or propagated on in one or more computer readable medium(s).

The computer readable medium may be a tangible computer readable storage medium storing the program code. The computer readable storage medium may be, for example, but not limited to, an electronic, magnetic, optical, electromagnetic, infrared, holographic, micromechanical, or semiconductor system, apparatus, or device, or any suitable combination of the foregoing.

More specific examples of the computer readable storage medium may include but are not limited to a portable computer diskette, a hard disk, a random access memory (“RAM”), a read-only memory (“ROM”), an erasable programmable read-only memory (“EPROM” or Flash memory), a portable compact disc read-only memory (“CD-ROM”), a digital versatile disc (“DVD”), an optical storage device, a magnetic storage device, a holographic storage medium, a micromechanical storage device, or any suitable combination of the foregoing. In the context of this document, a computer readable storage medium may be any tangible medium that can contain, and/or store program code for use by and/or in connection with an instruction execution system, apparatus, or device.

The computer readable medium may also be a computer readable signal medium. A computer readable signal medium may include a propagated data signal with program code embodied therein, for example, in baseband or as part of a carrier wave. Such a propagated signal may take any of a variety of forms, including, but not limited to, electrical, electro-magnetic, magnetic, optical, or any suitable combination thereof. A computer readable signal medium may be any computer readable medium that is not a computer readable storage medium and that can communicate, propagate, or transport program code for use by or in connection with an instruction execution system, apparatus, or device. Program code embodied on a computer readable signal medium may be transmitted using any appropriate medium, including but not limited to wire-line, optical fiber, Radio Frequency (“RF”), or the like, or any suitable combination of the foregoing

In one embodiment, the computer readable medium may comprise a combination of one or more computer readable storage mediums and one or more computer readable signal mediums. For example, program code may be both propagated as an electro-magnetic signal through a fiber optic cable for execution by a processor and stored on RAM storage device for execution by the processor.

Program code for carrying out operations for aspects of the present invention may be written in any combination of one or more programming languages, including an object oriented programming language such as Java, Smalltalk, C++, PHP or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (“LAN”) or a wide area network (“WAN”), or the connection may be made to an external computer (for example, through the Internet using an Internet Service Provider). The computer program product may be shared, simultaneously serving multiple customers in a flexible, automated fashion.

The computer program product may be integrated into a client, server and network environment by providing for the computer program product to coexist with applications, operating systems and network operating systems software and then installing the computer program product on the clients and servers in the environment where the computer program product will function. In one embodiment software is identified on the clients and servers including the network operating system where the computer program product will be deployed that are required by the computer program product or that work in conjunction with the computer program product. This includes the network operating system that is software that enhances a basic operating system by adding networking features.

Furthermore, the described features, structures, or characteristics of the embodiments may be combined in any suitable manner. In the following description, numerous specific details are provided, such as examples of programming, software modules, user selections, network transactions, database queries, database structures, hardware modules, hardware circuits, hardware chips, etc., to provide a thorough understanding of embodiments. One skilled in the relevant art will recognize, however, that embodiments may be practiced without one or more of the specific details, or with other methods, components, materials, and so forth. In other instances, well-known structures, materials, or operations are not shown or described in detail to avoid obscuring aspects of an embodiment.

Aspects of the embodiments are described below with reference to schematic flowchart diagrams and/or schematic block diagrams of methods, apparatuses, systems, and computer program products according to embodiments of the invention. It will be understood that each block of the schematic flowchart diagrams and/or schematic block diagrams, and combinations of blocks in the schematic flowchart diagrams and/or schematic block diagrams, can be implemented by program code. The program code may be provided to a processor of a general purpose computer, special purpose computer, sequencer, or other programmable data processing apparatus to produce a machine, such that the instructions, which execute via the processor of the computer or other programmable data processing apparatus, create means for implementing the functions/acts specified in the schematic flowchart diagrams and/or schematic block diagrams block or blocks.

The program code may also be stored in a computer readable medium that can direct a computer, other programmable data processing apparatus, or other devices to function in a particular manner, such that the instructions stored in the computer readable medium produce an article of manufacture including instructions which implement the function/act specified in the schematic flowchart diagrams and/or schematic block diagrams block or blocks.

The program code may also be loaded onto a computer, other programmable data processing apparatus, or other devices to cause a series of operational steps to be performed on the computer, other programmable apparatus or other devices to produce a computer implemented process such that the program code which executed on the computer or other programmable apparatus provide processes for implementing the functions/acts specified in the flowchart and/or block diagram block or blocks.

The schematic flowchart diagrams and/or schematic block diagrams in the Figures illustrate the architecture, functionality, and operation of possible implementations of apparatuses, systems, methods and computer program products according to various embodiments of the present invention. In this regard, each block in the schematic flowchart diagrams and/or schematic block diagrams may represent a module, segment, or portion of code, which comprises one or more executable instructions of the program code for implementing the specified logical function(s).

It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated Figures.

Although various arrow types and line types may be employed in the flowchart and/or block diagrams, they are understood not to limit the scope of the corresponding embodiments. Indeed, some arrows or other connectors may be used to indicate only the logical flow of the depicted embodiment. For instance, an arrow may indicate a waiting or monitoring period of unspecified duration between enumerated steps of the depicted embodiment. It will also be noted that each block of the block diagrams and/or flowchart diagrams, and combinations of blocks in the block diagrams and/or flowchart diagrams, can be implemented by special purpose hardware-based systems that perform the specified functions or acts, or combinations of special purpose hardware and program code.

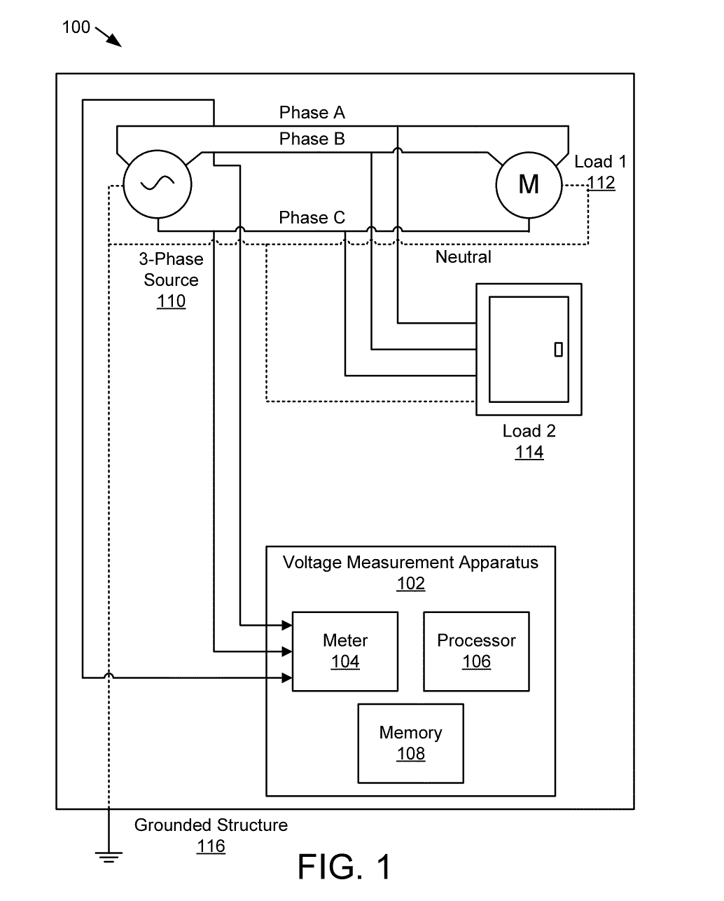

FIG. 1 is a schematic block diagram illustrating one embodiment of a system 100 for determining voltages. The system 100 includes a voltage measurement apparatus 102, which in some embodiments may include a meter 104, a processor 106 and/or memory 108, a three-phase voltage source 110, a first load 112 and a second load 114 connected to the voltage source 110 with a phase A, a phase B, and a phase C, and may include a grounded structure 116, which are described below.

The system 100 includes a voltage measurement apparatus 102 that determines line-to-neutral voltages. In one embodiment, the voltage measurement apparatus 102 determines line-to-neutral voltages from line-to-line voltage of a three-phase power system, such as the system 100 depicted in FIG. 1. The voltage measurement apparatus 102, in one embodiment, calculates line-to-neutral voltage where a neutral is not available. For instance, the three-phase voltage source 110 may be isolated from a grounded structure 116 and loads of the system 100 (e.g. the first and second loads 112, 114) may be three-phase loads without a neutral connection.

In one embodiment, the voltage measurement apparatus 102 includes a meter 104. The meter 104, in one example, is located with the voltage measurement apparatus 102. For example, functionality of the voltage measurement apparatus 102 may be included in the meter 104. For example, the meter 104 may be a PowerMonitor 5000™ by Allen-Bradley® and functionality of the voltage measurement apparatus 102 may be incorporated into the PowerMonitor 5000. In another embodiment, the meter 104 may be apart from the voltage measurement apparatus 102. For example, the meter 104 may measure voltages and may send voltage measurement information to the voltage measurement apparatus 102. In another embodiment, a portion of the meter 104 may be located external to the voltage measurement apparatus 102 while a portion is within the voltage measurement apparatus 102.

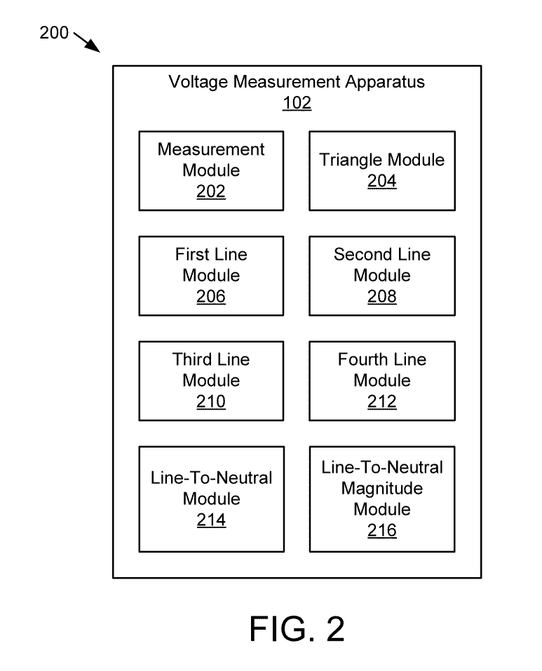

In another embodiment, the voltage measurement apparatus 102 includes a processor 106 and/or memory 108. The processor 106 may execute code associated with the voltage measurement apparatus 102. For example, the voltage measurement apparatus 102 may be embodied by computer program product for determining a voltage. The computer program product may be stored on a computer readable storage medium, such as the memory 108. The memory 108 may include RAM, ROM, a hard disk drive, etc. that has the program code embodied therein and the program code may be readable/executable by the processor 106. In another embodiment, the voltage measurement apparatus 102 is fully or partially embodied by logic hardware and may be embodied in part, in some embodiments, by executable code. Functionality of the voltage measurement apparatus 102 is explained further in the apparatus 200 of FIG. 2.

The system 100, in one embodiment, includes a three-phase voltage source 110. The three-phase voltage source 110 may be three-phase power from an electric utility, may be a generator, may be an uninterruptable power supply, may be a switching power supply, or other power source that provides three-phase power. Three-phase power, in one embodiment, includes three sinusoidal voltage waveforms offset by 120 degrees. The waveforms may include a sinusoidal fundamental frequency waveform and may include harmonic waveforms. The sinusoidal fundamental frequency waveform of the three waveforms is each offset by 120 degrees.

In one embodiment, the system 100 includes one or more loads, for example the first load 112 and the second load 114. The first load 112 may be a motor, such as a three-phase motor. Often three-phase motors do not include a neutral connection and a neutral wire is not run between the three-phase voltage source 110 and the motor load 112. The second load 114 may be a branch panel. While branch panels typically include a neutral connection, in some examples a transformer (not shown) is located between the branch panel 114 and the three-phase voltage source 110 and the transformer may be a delta-wye transformer where no neutral is run upstream of the transformer. Other loads and power system configurations may also not have a neutral connection or ground connection available. In some embodiments, a grounded structure 116 or earth ground may not be available, for example for floating power systems that require isolation from ground.

Typically, the three waveforms from the three-phase voltage source 110 are balanced so that line-to-line voltages are equal and line-to-neutral voltages are equal. During this condition, determining line-to-neutral voltage from line-to-line voltage may reasonably be determined by dividing the line-to-line voltage by the square root of three. When the three voltage waveforms from the three-phase voltage source 110 or as measured at some point within the system 100 become unbalanced, determination of line-to-neutral voltage from the line-to-line voltages is not trivial. The voltage measurement apparatus 102 may be used to determine line-to-neutral voltages from line-to-line voltages.

FIG. 2 is a schematic block diagram illustrating one embodiment of an apparatus 200 for determining voltages. The apparatus 200 includes a measurement module 202, a triangle module 204, a first line module 206, a second line module 208, a third line module 210, a fourth line module 212, a line-to-neutral module 214, and in some embodiments, a line-to-neutral magnitude module 216, which are described below.

The apparatus 200, in one embodiment, includes a measurement module 202 that measures three line-to-line voltages for the phases in a three-phase power system, such as the system 100 depicted in FIG. 1. Each line-to-line voltage includes a voltage magnitude. For example, the line-to-line voltage magnitude may be a root-mean-square (“RMS”) voltage measured between two phases. For instance the measurement module 202 may measure RMS voltages. The measurement module 202 may connect to each of the three phases A, B, and C, and a line-to-line measurement may be between Phase A and Phase B, between Phase B and Phase C, or between Phase C and Phase A. In another embodiment, the voltage magnitude may be a peak voltage. For example, the peak voltage may be a highest voltage within a cycle of a fundamental sinusoidal frequency within the three line-to-line voltages and the measurement module 202 may measure a peak voltage of the three phases, A, B, and C. The peak voltages, in another embodiment, are converted RMS voltage measurements. One example of the measurement module 202 is the meter 104 depicted in the system 100 of FIG. 1.

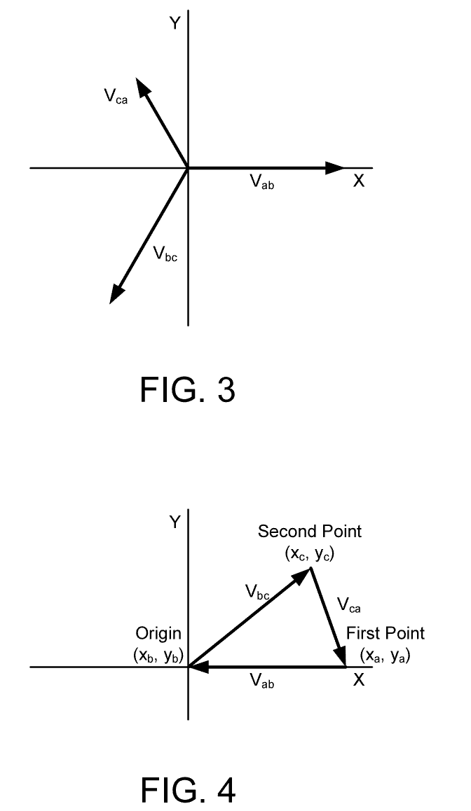

The apparatus 200, in one embodiment, includes a triangle module 204 that constructs, on a two-dimensional coordinate system with an origin, a phasor triangle that includes the three line-to-line voltages, measured by the measurement module 202, represented as phasors. A first phasor V_{ab} originates at a first point and extends in a direction along a horizontal axis of the coordinate system to the origin of the coordinate system. A second phasor V_{bc} extends between the origin and a second point. The second point is in a direction vertically and horizontally from the origin. A third phasor V_{ca} extends between the second point and the first point. An example of a phasor triangle constructed from three line-to-line voltage phasors of FIG. 3 is shown in FIG. 4. In FIG. 3, the third phasor V_{ca} is two-thirds the voltage of the first and second phasors, V_{ab} and V_{bc}.

FIG. 3 is a diagram of voltages of a three-phase power system with unbalanced voltages. FIG. 4 is a diagram of the voltages of the three-phase power system with unbalanced voltages repositioned as a phasor triangle. FIG. 3 is a typical phasor diagram with phasor V_{ab} oriented at zero degrees, phasor V_{bc} at 120 degrees, and phasor V_{ca} at −120 degrees (240 degrees) where angles are measured clockwise from the positive X axis. Note that with a voltage imbalance, angles between the voltage phasors V_{ab}, V_{bc}, and V_{ca} change from the 120 degree separation in FIG. 3 and angles of the phasor triangle are determined by magnitudes of the phasors. The first point is at the termination of phasor V_{ab} and is (xₐ, yₐ) so xₐ=V_{ab} and y_{b}=0. The origin is (x_{b}, y_{b}) so x_{b}=0 and y_{b}=0. The second point is (x_{c}, y_{c}) and may be determined using the law of cosines, where

$$\begin{matrix}{x}_{c} = \frac{{V}_{ab}^{2} - {V}_{ca}^{2} + {V}_{bc}^{2}}{2 \cdot {V}_{ab}} & Equation ( 1 ) \\ {y}_{c} = {V}_{ca} \cdot \sqrt{1 - ( \frac{{V}_{bc}^{2} - {V}_{ab}^{2} - {V}_{ca}^{2}}{4 \cdot {V}_{ab}^{2} \cdot {V}_{ca}^{2}} )} & Equation ( 2 )\end{matrix}$$

V_{ab}, V_{bc}, and V_{ca} are magnitudes of the three line-to-line voltages measured by the measurement module 202.

### First Geometric Method

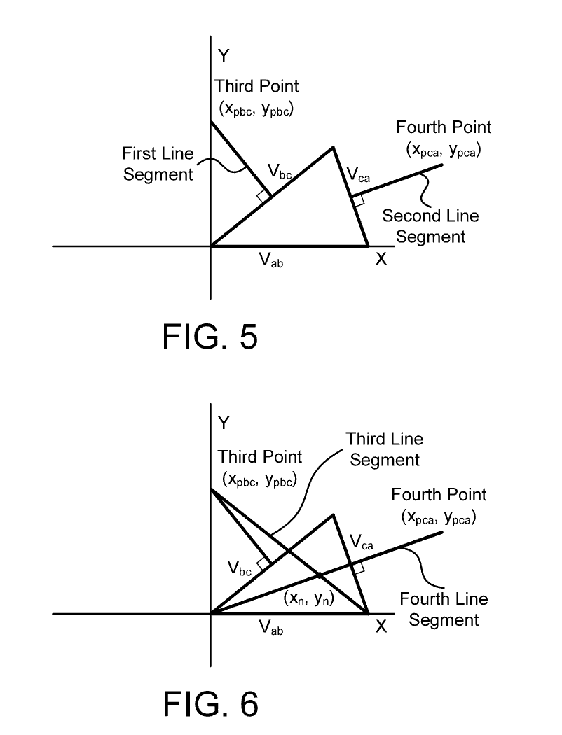

The apparatus 200, in one embodiment, includes a first line module 206 that adds a first line segment that extends from a point that bisects the second phasor V_{bc} in a direction perpendicular to the second phasor V_{bc} and away from the phasor triangle. The first line segment terminates at a third point. FIG. 5 is a diagram of voltages of a three-phase power system with unbalanced voltages repositioned as a phasor triangle with perpendicular lines bisecting two sides using a first geometric method. FIG. 5 depicts the first line segment for the first geometric method. In the embodiment, the first line segment terminates at a third point, (x_{pbc}, y_{pbc}). In the depicted first geometric method, the length of the first line segment has a magnitude of the third phasor V_{ca} divided by the square root of three and multiplied by the square root of one plus the square of the slope of the first line segment. A second geometric method for is depicted in FIGS. 8-10. The slope of the first line segment may be expressed as:

$${slope}_{pbc} = \frac{- {x}_{c}}{{y}_{c}} \qquad Equation ( 3 )$$

The length of the first line segment, in one embodiment, then may be expressed as:

$$\frac{{V}_{ca}}{\sqrt{3}} \cdot \sqrt{1 + {( \frac{- {x}_{c}}{{y}_{c}} )}^{2}} \qquad Equation ( 4 )$$

From the position and length of the first line segment, in one example, the third point may be determined as:

$$\begin{matrix}{x}_{pbc} = \frac{{x}_{c}}{2} - \frac{{V}_{ca}}{\sqrt{3}} & Equation ( 5 ) \\ {y}_{pbc} = \frac{{y}_{c}}{2} - \frac{- {x}_{c}}{{y}_{c}} \cdot \frac{{V}_{ca}}{\sqrt{3}} & Equation ( 6 )\end{matrix}$$

In one embodiment, the apparatus 200 includes a second line module 208 that adds a second line segment that extends from a point that bisects the third phasor V_{ca} in a direction perpendicular to the third phasor V_{ca} and away from the phasor triangle. The second line segment terminates at a fourth point. FIG. 5 also depicts the second line segment for the first geometric method. In the embodiment, the second line segment terminates at a fourth point, (x_{pca}, y_{pca}). In the first geometric method, the length of the second line segment has a magnitude of the second phasor V_{bc} divided by the square root of three and multiplied by the square root of one plus the square of the slope of the second line segment. In one embodiment, the slope of the second line segment may be expressed as:

$${slope}_{pca} = \frac{- ( {x}_{a} - {x}_{c} )}{( {y}_{a} - {y}_{c} )} \qquad Equation ( 7 )$$

In another embodiment, the length of the second line segment then may be expressed as:

$$\frac{{V}_{bc}}{\sqrt{3}} \cdot \sqrt{1 + {( \frac{- ( {x}_{a} - {x}_{c} )}{( {y}_{a} - {y}_{c} )} )}^{2}} \qquad Equation ( 8 )$$

From the position and length of the second line segment, the fourth point may be determined as:

$$\begin{matrix}{x}_{pca} = {x}_{c} + \frac{{x}_{a} - {x}_{c}}{2} + \frac{{V}_{bc}}{\sqrt{3}} & Equation ( 9 ) \\ {x}_{pca} = \frac{{y}_{c}}{2} + \frac{- ( {x}_{a} - {x}_{c} )}{( {y}_{a} - {y}_{c} )} \cdot \frac{{V}_{bc}}{\sqrt{3}} & Equation ( 10 )\end{matrix}$$

The apparatus 200, in one embodiment, includes a third line module 210 that adds a third line segment from the third point to the first point and a fourth line module 212 that adds a fourth line segment from the fourth point to the origin. The third line segment intersects the fourth line segment at a neutral point, (xₙ, yₙ). FIG. 6 is a diagram, consistent with the first geometric method, of voltages of a three-phase power system with unbalanced voltages repositioned as a phasor triangle with perpendicular lines bisecting two sides and lines intersecting a neutral point. FIG. 6 depicts the neutral point (xₙ, yₙ). The slope of the third line segment may be expressed as:

$${slope}_{3 rd} = \frac{- {y}_{pbc}}{{x}_{a} - {x}_{pbc}} \qquad Equation ( 11 )$$

An equation for the third line segment is y=slope_{3rd}·x+Z where Z=−slope_{3rd}·xₐ. The slope of the fourth line segment may be expressed as:

$${slope}_{4 th} = \frac{{y}_{pca}}{{x}_{pca}} \qquad Equation ( 12 )$$

An equation for the fourth line segment is y=slope₄ₜₕ·x. The x-coordinate of the intersection of the third and fourth lines segments may be expressed as:

$${x}_{n} = \frac{z}{{slope}_{4 th} - {slope}_{3 rd}} \qquad Equation ( 13 )$$

The y-coordinate of the intersection of the third and fourth line segments may be expressed as:

yₙ=slope₄ₜₕ·xₙ Equation (14)

The neutral point (xₙ, yₙ), in one embodiment, may then be expressed as:

$$\begin{matrix}{x}_{n} = \frac{\frac{{y}_{pbc}}{{x}_{a} - {x}_{pbc}} \times {x}_{a}}{\frac{{y}_{pca}}{{x}_{pca}} + \frac{{y}_{pbc}}{{x}_{a} - {x}_{pbc}}} & Equation ( 15 ) \\ {y}_{n} = \frac{{y}_{pca}}{{x}_{pca}} \cdot {x}_{n} & Equation ( 16 )\end{matrix}$$

The apparatus 200, in one embodiment, includes a line-to-neutral module 214 that determines a line-to-neutral voltage where the line-to-neutral voltage is a line from the neutral point to a vertex of the phasor triangle. In one embodiment, the line-to-neutral module 214 determines the line-to-neutral voltage for a phasor Vₐₙ for phase A, which includes determining a line from the neutral point to the first point. In another embodiment, the line-to-neutral module 214 determines the line-to-neutral voltage for a phasor V_{bn} for phase B, which includes determining a line from the neutral point to the origin. In another embodiment, the line-to-neutral module 214 determines the line-to-neutral voltage for a phasor V_{cn} for phase C, which includes determining a line from the neutral point to the second point.

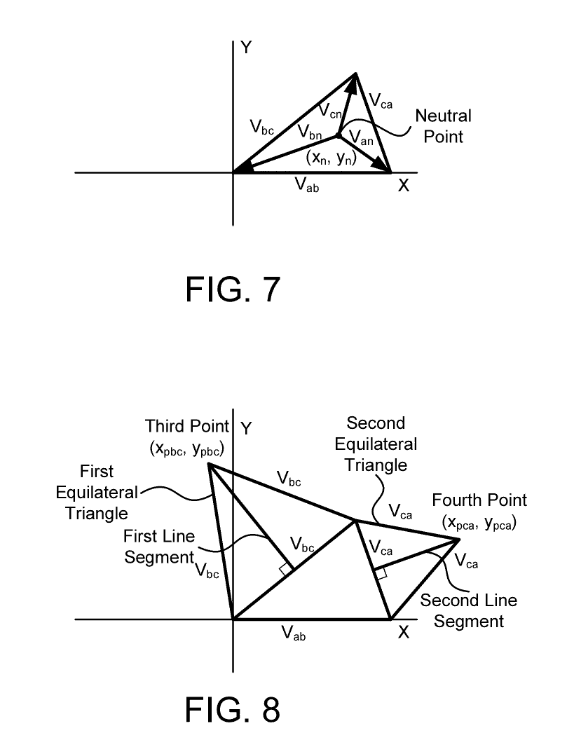

FIG. 7 is a diagram of voltages of a three-phase power system with unbalanced voltages repositioned as a phasor triangle with line-to-neutral phasors shown from the neutral point. FIG. 7 depicts the phasor Vₐₙ for phase A, the phasor V_{bn} for phase B, and the phasor V_{cn} for phase C. In one embodiment, the apparatus 200 includes a line-to-neutral magnitude module 216 that determines a magnitude of the line-to-neutral voltage phasors. In one embodiment, the line-to-neutral magnitude module 216 determines magnitudes of the line-to-neutral phasors as:

Vₐₙ=\sqrt{(xₐ−xₙ)²+(yₐ−yₙ)²} Equation (17)

V_{bn}=\sqrt{(x_{b}−xₙ)²+(y_{b}−yₙ)²} Equation (18)

V_{cn}=\sqrt{(x_{c}−xₙ)²+(y_{c}−yₙ)²} Equation (19)

The equations listed above may be less computationally intensive than other methods of calculating line-to-neutral voltages from line-to-line voltages. For example, the equations do not use sine or cosine functions.

In some embodiments, certain extreme voltage imbalance may cause the neutral point to be outside the phasor triangle. For example, in the case of a phase loss, the neutral point may be slightly outside the phasor triangle. For instance, as certain equations have a denominator that approaches zero, the equations may calculate a neutral point outside the phasor triangle. To correct for these situations, in one embodiment the following equations may be used to correct the neutral point location:

$$\begin{matrix}{y}_{n} := if {y}_{n } < 0 then {y}_{n} = 0 ; \\ else if {y}_{n} > {y}_{c} , then {y}_{n} = {y}_{c} ; else {y}_{n} . & Equation ( 20 ) \\ {x}_{n} := if {x}_{n} < 0 then {x}_{n} = 0 ; \\ else if {x}_{n} > {x}_{a} then {x}_{n} = {x}_{a} ; \\ else if {y}_{c} = {y}_{a} then {x}_{n} = {x}_{c} ; else {x}_{n} = {x}_{n} . & Equation ( 21 )\end{matrix}$$

### Second Geometric Method

For the second geometric method, the first line module 206 again adds a first line segment that extends from a point that bisects the second phasor V_{bc} in a direction perpendicular to the second phasor V_{bc} and away from the phasor triangle and the first line segment terminates at a third point. However, the third point, (x_{pbc}, y_{pbc}) terminates at a point that is a vertex of a first equilateral triangle formed along the second phasor V_{bc} and away from the phasor triangle where the three sides of the equilateral triangle all have a length of the magnitude of the second phasor V_{bc}. The length of the first line segment is the magnitude of the second phasor V_{bc} multiplied by the square root of three and divided by two.

Also for the second geometric method, the second line module 208 again adds a second line segment that extends from a point that bisects the second phasor V_{bc} in a direction perpendicular to the third phasor V_{ca} and away from the phasor triangle and the second line segment terminates at a fourth point. However, the fourth point, (x_{pca}, y_{pca}) terminates at a point that is a vertex of a second equilateral triangle formed along the third phasor V_{ca} and away from the phasor triangle where the three sides of the equilateral triangle all have a length of the magnitude of the third phasor V_{ca}. The length of the second line segment is the magnitude of the third phasor V_{ca} multiplied by the square root of three and divided by two. FIG. 8 depicts the first and second equilateral triangles. The first equilateral triangle has sides equal to the second phasor V_{bc}. The second equilateral triangle has sides equal to the third phasor V_{ca}. The first line segment terminates at the third point at a vertex of the first equilateral triangle and the second line segment terminates at the fourth point at a vertex of the second equilateral triangle.

The slope of the first line segment is the same as stated above in Equation 3. Also, the slope of the second line segment is as stated above in Equation 7. From the position and length of the first line segment, in one example, the third point and the fourth point may be determined as:

$$\begin{matrix}{x}_{pbc} = \frac{{x}_{c} - {y}_{c} \cdot \sqrt{3}}{2} & Equation ( 22 ) \\ {y}_{pbc} = \frac{{y}_{c} + {x}_{c} \cdot \sqrt{3}}{2} & Equation ( 23 ) \\ {x}_{pca} = {x}_{a} + \frac{{x}_{c} - {x}_{a} + \sqrt{3} \cdot {y}_{c}}{2} & Equation ( 24 ) \\ {y}_{pca} = \frac{( {y}_{c} - {y}_{a} ) + \sqrt{3} \cdot ( {x}_{a} - {x}_{c} )}{2} & Equation ( 25 )\end{matrix}$$

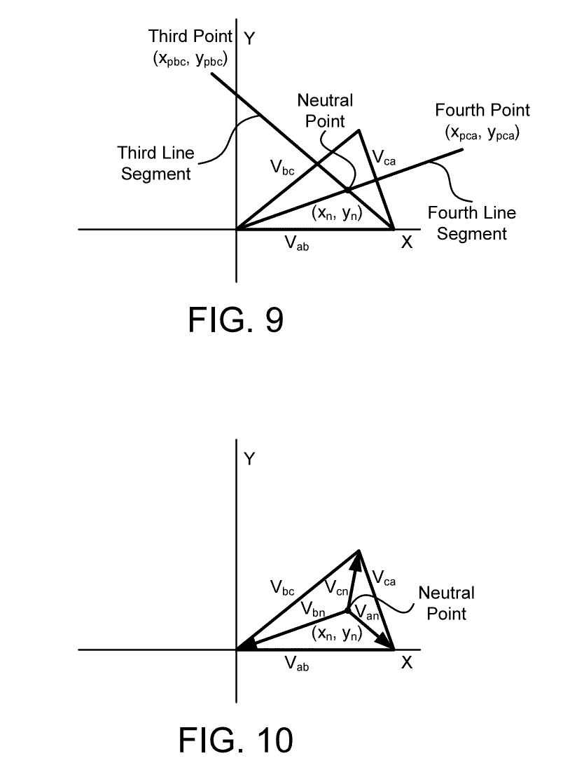

Again, the third line module 210 adds a third line segment from the third point to the first point and the fourth line module 212 adds a fourth line segment from the fourth point to the origin. The third line segment again intersects the fourth line segment at a neutral point, (xₙ, yₙ). Consistent with the second geometric method, FIG. 9 is a diagram of voltages of a three-phase power system with unbalanced voltages repositioned as a phasor triangle with perpendicular lines bisecting two sides and lines intersecting a neutral point. FIG. 9 again depicts the neutral point (xₙ, yₙ). The slope of the third line segment may be expressed as stated above in Equation 11. An equation for the third line segment is y=slope_{3rd}·x+Z where Z=−slope_{3rd}·xₐ. The slope of the fourth line segment may be expressed as stated above in Equation 12. An equation for the fourth line segment is y=slope₄ₜₕ·x. The x-coordinate of the intersection of the third and fourth lines segments may be expressed as stated above in Equation 13. The y-coordinate of the intersection of the third and fourth line segments may be expressed as stated above in Equation 14.

The neutral point (xₙ, yₙ), in one embodiment, may then be expressed as:

$$\begin{matrix}{x}_{n} = \frac{\frac{{x}_{a} \cdot {y}_{pbc}}{{x}_{a} - {x}_{pbc}}}{\frac{{y}_{pca}}{{x}_{pca}} + \frac{{y}_{pbc}}{{x}_{a} - {x}_{pbc}}} & Equation ( 26 ) \\ {y}_{n} = \frac{{y}_{pca}}{{x}_{pca}} \cdot {x}_{n} & Equation ( 27 )\end{matrix}$$

The neutral point may be called the isogonic center, which is a point inside of a triangle where no interior angle is greater than 120 degrees and where an observer would see the vertices at equal degree distances, e.g. 120 degrees apart. Typically the neutral point for the second geometric method remains within the phasor triangle and the line-to-neutral voltages are at a constant 120 degrees apart typically due to machine geometry. However, machine error may cause variations, for example when denominators are small. The line-to-neutral module 214 again determines a line-to-neutral voltage where the line-to-neutral voltage is a line from the neutral point to a vertex of the phasor triangle. In one embodiment, the line-to-neutral module 214 determines the line-to-neutral voltage for a phasor Vₐₙ for phase A, which includes determining a line from the neutral point to the first point. In another embodiment, the line-to-neutral module 214 determines the line-to-neutral voltage for a phasor V_{bn} for phase B, which includes determining a line from the neutral point to the origin. In another embodiment, the line-to-neutral module 214 determines the line-to-neutral voltage for a phasor V_{cn} for phase C, which includes determining a line from the neutral point to the second point.

Consistent with the second geometric method, FIG. 10 is a diagram of voltages of a three-phase power system with unbalanced voltages repositioned as a phasor triangle with line-to-neutral phasors shown from the neutral point. FIG. 10 depicts the phasor Vₐₙ for phase A, the phasor V_{bn} for phase B, and the phasor V_{cn} for phase C. The line-to-neutral magnitude module 216 determines a magnitude of the line-to-neutral voltage phasors. The line-to-neutral magnitude module 216 determines magnitudes of the line-to-neutral phasors as stated above in Equations 17, 18 and 19.

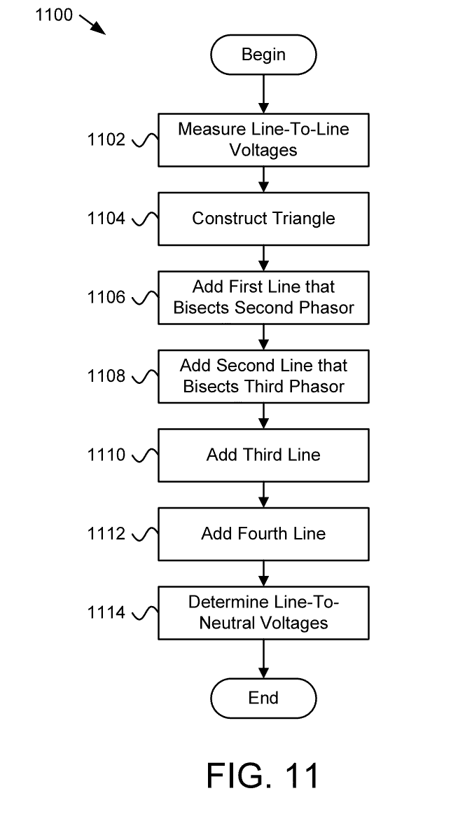

FIG. 11 is a schematic flow chart diagram illustrating one embodiment of a method 1100 for determining voltages. The method 1100 begins and measures 1102 three line-to-line voltages for the phases in a three-phase power system, such as the system 100 depicted in FIG. 1. Each line-to-line voltage includes a voltage magnitude. In one embodiment, the measurement module 202 measures the three line-to-line voltages.

The method 1100 constructs 1104, on a two-dimensional coordinate system with an origin, a phasor triangle with the three line-to-line voltages represented as phasors, where a first phasor V_{ab} originates at a first point and extends in a direction along a horizontal axis of the coordinate system to the origin, a second phasor V_{bc} extends between the origin and a second point, the second point in a direction vertically and horizontally from the origin, and a third phasor V_{ca} extends between the second point and the first point. In one embodiment, the triangle module 204 constructs the phasor triangle.

The method 1100 adds 1106 a first line segment that extends from a point that bisects the second phasor V_{bc} in a direction perpendicular to the second phasor V_{bc} and away from the phasor triangle. The first line segment terminates at a third point. For the first geometric method, the length of the first line segment has a magnitude of the third phasor V_{ca} divided by the square root of three and multiplied by the square root of one plus the square of the slope of the first line segment. For the second geometric method, the length of the first line segment is the magnitude of the second phasor V_{bc} multiplied by the square root of three and divided by two. The first line module 206, in one embodiment, adds 1106 the first line segment.

The method 1100 adds 1108 a second line segment that extends from a point that bisects the third phasor V_{ca} in a direction perpendicular to the third phasor V_{ca} and away from the phasor triangle. The second line segment terminates at a fourth point. For the first geometric method, the length of the second line segment has a magnitude of the second phasor V_{bc} divided by the square root of three and multiplied by the square root of one plus the square of the slope of the second line segment. For the second geometric method, the length of the second line segment is the magnitude of the third phasor V_{ca} multiplied by the square root of three and divided by two. The second line module 208, in one example, adds 1108 the second line segment.

The method 1100 adds 1110 a third line segment from the third point to the first point and adds 1112 a fourth line segment from the fourth point to the origin. The third line segment intersects the fourth line segment at a neutral point. In one embodiment, the third line module 210 adds 1110 the third line segment and the fourth line module 212 adds 1112 the fourth line segment. The method 1100 determines 1114 a line-to-neutral voltage where the line-to-neutral voltage is a line from the neutral point to a vertex of the phasor triangle, and the method 1100 ends. The line-to-neutral module 214, in one embodiment, determines 1114 the line-to-neutral voltages.

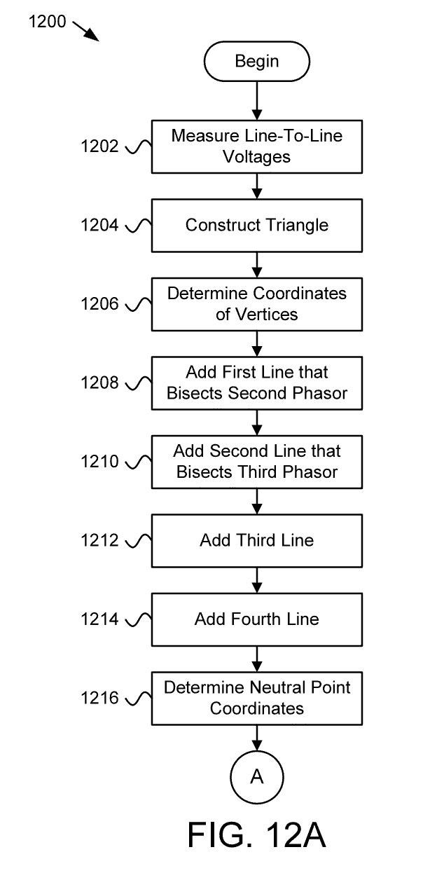

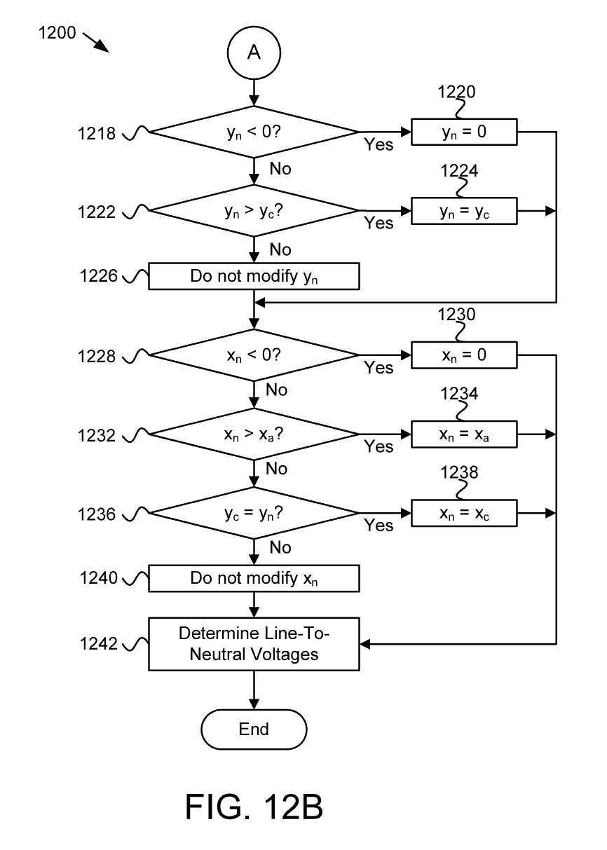

FIG. 12A is a first part and FIG. 12B is a second part of a schematic flow chart diagram illustrating another embodiment of a method 1200 for determining voltages. The method 1200 begins and measures 1202 three line-to-line voltages for the phases in a three-phase power system, such as the system 100 depicted in FIG. 1. Each line-to-line voltage includes a voltage magnitude. The method 1200 constructs 1204, on a two-dimensional coordinate system with an origin, a phasor triangle with the three line-to-line voltages represented as phasors, where a first phasor V_{ab} originates at a first point and extends in a direction along a horizontal axis of the coordinate system to the origin, a second phasor V_{bc} extends between the origin and a second point, the second point in a direction vertically and horizontally from the origin, and a third phasor V_{ca} extends between the second point and the first point.

The method 1200 determines 1206 coordinates of the vertices of the phasor triangle. For example, the method 1200 may determine 1206 that the first point is at the termination of phasor V_{ab} and is (xₐ, yₐ) so xₐ=V_{ab} and y_{b}=0. The origin is (x_{b}, y_{b}) so the method 1200 may determine 1206 that x_{b}=0 and y_{b}=0. The method 1200 may determine 1206 the second point (x_{c}, y_{c}) using equations 1 and 2.

The method 1200 adds 1208 a first line segment that extends from a point that bisects the second phasor V_{bc} in a direction perpendicular to the second phasor V_{bc} and away from the phasor triangle. The first line segment terminates at a third point. For the first geometric method, the length of the first line segment has a magnitude of the third phasor V_{ca} divided by the square root of three and multiplied by the square root of one plus the square of the slope of the first line segment. For the second geometric method, the length of the first line segment is the magnitude of the second phasor V_{bc} multiplied by the square root of three and divided by two. The method 1200 adds 1210 a second line segment that extends from a point that bisects the third phasor V_{ca} in a direction perpendicular to the third phasor V_{ca} and away from the phasor triangle. The second line segment terminates at a fourth point. For the first geometric method, the length of the second line segment has a magnitude of the second phasor V_{bc} divided by the square root of three and multiplied by the square root of one plus the square of the slope of the second line segment. For the second geometric method, the length of the second line segment is the magnitude of the third phasor V_{ca} multiplied by the square root of three and divided by two.

The method 1200 adds 1212 a third line segment from the third point to the first point and adds 1214 a fourth line segment from the fourth point to the origin. The third line segment intersects the fourth line segment at a neutral point. The method 1200 determines 1216 coordinates of a neutral point (xₙ, yₙ). Theoretically, steps 1218-1240 are be more applicable to the first geometric method than the second geometric method for voltages greater than zero. However, calculation error and possible negative voltage readings are possible so steps 1218-1240 may be used for both the first and the second geometric methods. The method 1200 determines 1218 if yₙ<0 (follow “A” on FIG. 12A to “A” on FIG. 12B). If the method 1200 determines that yₙ is less than zero, the method 1200 then assigns 1220 yₙ to be equal to zero. If the method 1200 determines 1218 that yₙ is not less than zero, then the method 1200 determines 1222 if yₙ is greater than y_{c}. If the method 1200 determines 1222 that yₙ is greater than y_{c}, then the method 1200 assigns 1224 yₙ to be equal to y_{c}. If the method 1200 determines 1222 that yₙ is not greater than y_{c}, the method 1200 determines 1226 that yₙ is not to be modified. For example, the method 1200 may use the results of equation 17 to determine yₙ without further modification.

The method 1200 determines 1228 if xₙ is less than zero. If the method 1200 determines 1228 if xₙ is less than zero, the method assigns 1230 xₙ to be equal to zero. If the method 1200 determines 1228 that xₙ is not less than zero, the method 1200 determines 1232 if xₙ is greater than xₐ. If the method 1200 determines 1232 that xₙ is greater than xₐ, the method 1200 assigns 1234 xₙ to be equal to xₐ. If the method 1200 determines 1232 that xₙ is not greater than xₐ, the method 1200 determines 1236 if y_{c} is greater than yₙ. If the method 1200 determines 1236 that y_{c} is greater than yₙ, the method 1200 assigns 1238 xₙ to be equal to x_{c}. If the method 1200 determines 1236 that y_{c} is not greater than yₙ, the method 1200 determines 1240 that xₙ is not to be modified. For example, the method 1200 may use the results of equation 16 to determine xₙ without further modification. The method 1200 determines 1242 a line-to-neutral voltage where the line-to-neutral voltage is a line from the neutral point to a vertex of the phasor triangle, and the method 1200 ends.

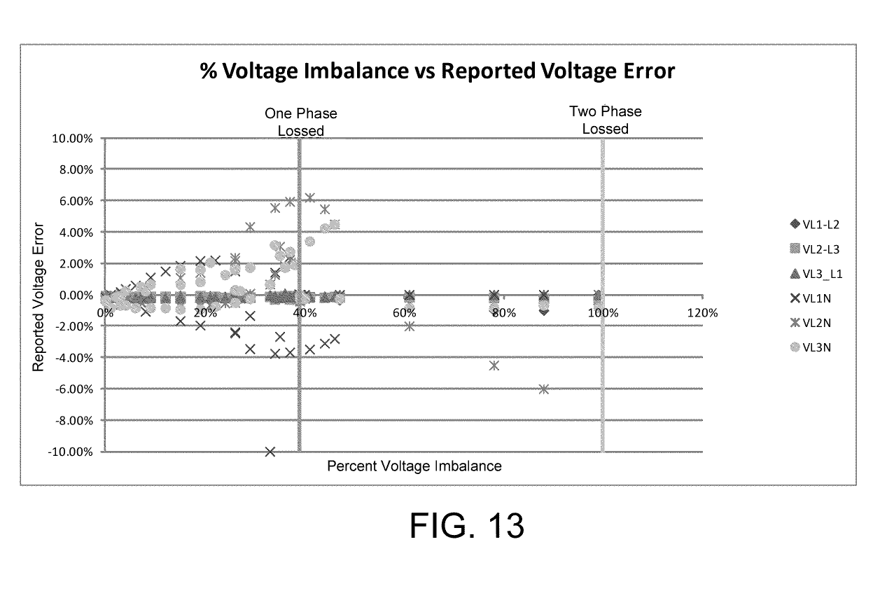

FIG. 13 is a plot of laboratory test results showing percent voltage imbalance versus reported voltage error for the first geometric method. Testing was completed using an apparatus similar to the apparatus 200 of FIG. 2 tested on a simple three-phase power system, which may be similar to the system 100 of FIG. 1. Data for FIG. 13 is shown in Table 1 and Table 2. Table 1 includes in the first three columns line-to-neutral voltage settings on the test equipment. The voltage settings vary on each phase between zero and 400 volts and represent various under and over-voltage conditions for three phases, 1, 2 and 3. The next three columns are expected line-to-line voltage conditions based on the test equipment settings. The next three columns are reported line-to-line voltages, which are reported from the metering device. The reported line-to-neutral voltages are the voltages calculated by the metering device using one embodiment of the apparatus 200 and methods 1100, 1200 described above in relation to FIGS. 2, 11, and 12. The calculated percent voltage imbalance of the second to last column is based on the test equipment set voltages and the reported percent voltage imbalance of the last column is the voltage imbalance reported by the metering device. The first three columns of Table 2 show reported line-to-line voltage error from expected line-to-line voltages as reported from the metering device. The last three columns of Table 2 show reported line-to-neutral voltage error comparing reported line-to-neutral voltages from the metering to the set line-to-neutral voltages.

FIG. 13 is a plot of the results in Table 2. FIG. 13 has percent voltage imbalance is shown on the horizontal axis and reported voltage error is shown on the vertical axis. VL1-L2 is the line-to-line voltage between a first and a second phase, VL2-L3 is the line-to-line voltage between the second and a third phase, and VL3-L1 is the line-to-line voltage between the third and the first phase. VL1N, VL2N and VL3N are line-to-neutral voltages for the first, second, and third phases, respectively. The “One Phase Lossed” line indicates a percent voltage imbalance corresponding to one phase of the 3-phase power system being shorted to ground and the “Two Phase Lossed” line indicated a percent voltage imbalance corresponding to when two phases are shorted to ground. Note that reported voltage error is greatest for when voltage approaches zero for one phase, but the error in most situations remains low. Two single phase loss conditions are represented in the graph. In one instance, the first phase (e.g. Phase A in the system 100 of FIG. 1) is reduced to zero, and in the second instance the second phase (e.g. Phase B in the system 100 of FIG. 1) is reduced to zero.

TABLE 1

| | | | | | | | | | | | | Calc. | Reported |
|---|---|---|---|---|---|---|---|---|---|---|---|---|---|
| Set L-N V | | | Expected L-L V | | | Reported L-L V | | | Reported L-N V | | | % V | % V |
| L1N | L2N | L3N | L12 | L23 | L31 | L12 | L23 | L31 | L1N | L2N | L3N | Imbal. | Imbal |
| 400 | 400 | 0 | 693 | 400 | 400 | 692 | 399 | 400 | 400 | 398 | 0 | 39% | 39% |
| 400 | 400 | 20 | 693 | 410 | 410 | 692 | 409 | 410 | 410 | 409 | 0 | 37% | 37% |
| 400 | 400 | 50 | 693 | 427 | 427 | 692 | 426 | 427 | 406 | 405 | 37 | 34% | 34% |
| 400 | 400 | 400 | 693 | 693 | 693 | 692 | 692 | 691 | 399 | 400 | 398 | 0% | 0% |
| 400 | 400 | 375 | 693 | 671 | 671 | 692 | 670 | 670 | 399 | 399 | 375 | 2% | 2% |
| 400 | 400 | 350 | 693 | 650 | 650 | 692 | 649 | 649 | 399 | 399 | 351 | 4% | 4% |
| 400 | 400 | 325 | 693 | 629 | 629 | 692 | 628 | 628 | 398 | 398 | 327 | 7% | 7% |
| 400 | 400 | 300 | 693 | 608 | 608 | 692 | 607 | 607 | 398 | 398 | 302 | 9% | 9% |
| 400 | 400 | 240 | 693 | 560 | 560 | 692 | 559 | 559 | 397 | 397 | 244 | 15% | 15% |
| 400 | 400 | 200 | 693 | 529 | 529 | 692 | 528 | 528 | 397 | 397 | 203 | 19% | 19% |
| 400 | 400 | 180 | 693 | 514 | 514 | 692 | 513 | 513 | 397 | 397 | 184 | 21% | 21% |
| 400 | 400 | 150 | 693 | 492 | 492 | 692 | 492 | 492 | 398 | 398 | 152 | 24% | 24% |
| 400 | 400 | 130 | 693 | 478 | 478 | 692 | 478 | 478 | 399 | 399 | 130 | 26% | 26% |
| 400 | 400 | 120 | 693 | 472 | 472 | 692 | 471 | 471 | 399 | 399 | 120 | 27% | 27% |
| 400 | 300 | 120 | 608 | 375 | 472 | 608 | 374 | 471 | 390 | 307 | 122 | 26% | 26% |
| 400 | 240 | 120 | 560 | 317 | 472 | 559 | 317 | 471 | 386 | 250 | 122 | 29% | 29% |
| 400 | 200 | 120 | 529 | 280 | 472 | 529 | 280 | 471 | 385 | 211 | 124 | 34% | 34% |
| 400 | 180 | 120 | 514 | 262 | 472 | 514 | 261 | 471 | 385 | 191 | 123 | 37% | 37% |
| 400 | 150 | 120 | 492 | 234 | 472 | 492 | 234 | 471 | 386 | 159 | 124 | 41% | 41% |
| 400 | 130 | 120 | 478 | 217 | 472 | 478 | 216 | 471 | 388 | 137 | 125 | 44% | 44% |
| 400 | 120 | 120 | 472 | 208 | 472 | 471 | 208 | 471 | 389 | 125 | 125 | 46% | 46% |
| 300 | 120 | 120 | 375 | 208 | 375 | 374 | 208 | 374 | 292 | 124 | 123 | 35% | 35% |
| 240 | 120 | 120 | 317 | 208 | 317 | 317 | 208 | 317 | 234 | 123 | 122 | 26% | 26% |
| 200 | 120 | 120 | 280 | 208 | 280 | 280 | 208 | 280 | 196 | 122 | 121 | 19% | 19% |
| 180 | 120 | 120 | 262 | 208 | 262 | 261 | 208 | 261 | 177 | 121 | 121 | 15% | 15% |
| 150 | 120 | 120 | 234 | 208 | 234 | 234 | 208 | 234 | 148 | 121 | 120 | 8% | 8% |
| 130 | 120 | 120 | 217 | 208 | 217 | 216 | 208 | 216 | 129 | 120 | 120 | 3% | 3% |
| 120 | 120 | 120 | 208 | 208 | 208 | 208 | 208 | 208 | 120 | 120 | 120 | 0% | 0% |
| 115 | 120 | 120 | 204 | 208 | 204 | 203 | 208 | 203 | 115 | 120 | 119 | 1% | 1% |
| 110 | 120 | 120 | 199 | 208 | 199 | 199 | 208 | 199 | 110 | 120 | 119 | 3% | 3% |
| 105 | 120 | 120 | 195 | 208 | 195 | 195 | 208 | 195 | 105 | 120 | 119 | 4% | 4% |
| 100 | 120 | 120 | 191 | 208 | 191 | 191 | 208 | 190 | 101 | 119 | 119 | 6% | 6% |
| 90 | 120 | 120 | 182 | 208 | 182 | 182 | 208 | 182 | 91 | 119 | 119 | 9% | 9% |
| 80 | 120 | 120 | 174 | 208 | 174 | 174 | 208 | 174 | 81 | 119 | 119 | 12% | 12% |
| 70 | 120 | 120 | 166 | 208 | 166 | 166 | 208 | 166 | 71 | 119 | 119 | 15% | 15% |
| 60 | 120 | 120 | 159 | 208 | 159 | 159 | 208 | 159 | 61 | 119 | 119 | 19% | 19% |
| 50 | 120 | 120 | 151 | 208 | 151 | 151 | 208 | 151 | 51 | 119 | 119 | 22% | 22% |
| 40 | 120 | 120 | 144 | 208 | 144 | 144 | 208 | 144 | 41 | 119 | 119 | 26% | 26% |
| 30 | 120 | 120 | 137 | 208 | 137 | 137 | 208 | 137 | 30 | 120 | 120 | 29% | 29% |
| 20 | 120 | 120 | 131 | 208 | 131 | 131 | 208 | 131 | 18 | 121 | 121 | 33% | 33% |
| 10 | 120 | 120 | 125 | 208 | 125 | 125 | 208 | 125 | 5.2 | 122 | 122 | 36% | 36% |
| 5 | 120 | 120 | 123 | 208 | 123 | 123 | 208 | 123 | 0 | 123 | 122 | 38% | 38% |
| 0 | 120 | 120 | 120 | 208 | 120 | 120 | 208 | 120 | 0 | 120 | 120 | 39% | 39% |
| 0 | 110 | 120 | 110 | 199 | 120 | 110 | 199 | 120 | 0 | 110 | 120 | 39% | 39% |
| 0 | 100 | 120 | 100 | 191 | 120 | 100 | 191 | 120 | 0 | 100 | 120 | 39% | 39% |
| 0 | 80 | 120 | 80 | 174 | 120 | 80 | 174 | 120 | 0 | 80 | 120 | 40% | 40% |
| 0 | 60 | 120 | 60 | 159 | 120 | 60 | 159 | 120 | 0 | 60 | 120 | 47% | 47% |
| 0 | 40 | 120 | 40 | 144 | 120 | 40 | 144 | 120 | 1.2 | 39 | 119 | 61% | 61% |
| 0 | 20 | 120 | 20 | 131 | 120 | 20 | 131 | 120 | 1.7 | 19 | 119 | 78% | 78% |
| 0 | 10 | 120 | 10 | 125 | 120 | 9.9 | 125 | 120 | 1.2 | 9.4 | 119 | 88% | 88% |
| 0 | 0 | 120 | 0 | 120 | 120 | 0.9 | 120 | 120 | 0.8 | 0.1 | 119 | 99% | 99% |

TABLE 2

| Reported Line-to-Line | | | | | |
|---|---|---|---|---|---|
| Voltage Error | | | Reported Line-to-Neutral | | |
| From Expected Value | | | Voltage Error | | |
| VL1-L2 | VL2-L3 | VL3_L1 | VL1N | VL2N | VL3N |
| −0.10% | −0.32% | −0.05% | −0.13% | 0.42% | — |
| −0.09% | −0.28% | −0.09% | 2.43% | 2.22% | 100.00% |
| −0.08% | −0.28% | −0.09% | 1.43% | 1.28% | −26.00% |
| −0.10% | −0.13% | −0.21% | −0.17% | 0.05% | −0.40% |
| −0.08% | −0.13% | −0.18% | −0.28% | 0.22% | −0.13% |
| −0.08% | −0.15% | −0.20% | −0.38% | 0.33% | 0.26% |
| −0.09% | −0.16% | −0.19% | −0.47% | 0.42% | 0.52% |
| −0.10% | −0.14% | −0.19% | −0.60% | 0.53% | 0.67% |
| −0.09% | −0.13% | −0.18% | −0.75% | 0.70% | 1.67% |
| −0.10% | −0.16% | −0.16% | −0.72% | 0.72% | 1.60% |
| −0.08% | −0.16% | −0.17% | −0.65% | 0.70% | 2.06% |
| −0.12% | −0.19% | −0.19% | −0.53% | 0.53% | 1.27% |
| −0.09% | −0.20% | −0.15% | −0.30% | 0.35% | 0.31% |
| −0.09% | −0.21% | −0.15% | −0.22% | 0.25% | 0.25% |
| −0.08% | −0.19% | −0.15% | −2.45% | 2.37% | 1.58% |
| −0.11% | −0.15% | −0.17% | −3.45% | 4.33% | 1.75% |
| −0.09% | −0.14% | −0.15% | −3.75% | 5.55% | 3.17% |
| −0.12% | −0.17% | −0.15% | −3.68% | 5.94% | 2.75% |
| −0.11% | −0.13% | −0.15% | −3.47% | 6.20% | 3.42% |
| −0.11% | −0.17% | −0.15% | −3.10% | 5.46% | 4.25% |
| −0.10% | −0.12% | −0.10% | −2.80% | 4.50% | 4.50% |
| −0.11% | −0.12% | −0.19% | −2.67% | 3.08% | 2.50% |
| −0.12% | −0.12% | −0.15% | −2.38% | 2.17% | 1.67% |
| −0.11% | −0.17% | −0.18% | −1.95% | 1.42% | 0.83% |
| −0.05% | −0.17% | −0.20% | −1.67% | 1.08% | 0.67% |
| −0.09% | −0.12% | −0.22% | −1.07% | 0.50% | 0.25% |
| −0.08% | −0.07% | −0.17% | −0.62% | 0.08% | −0.08% |
| −0.07% | −0.07% | −0.17% | −0.17% | 0.08% | −0.33% |
| −0.06% | −0.12% | −0.16% | 0.00% | 0.17% | −0.83% |
| −0.07% | −0.17% | −0.17% | 0.18% | 0.33% | −0.67% |
| −0.10% | −0.17% | −0.15% | 0.38% | 0.42% | −0.67% |
| −0.10% | −0.12% | −0.20% | 0.60% | 0.50% | −0.83% |
| −0.10% | −0.12% | −0.16% | 1.11% | 0.58% | −0.83% |
| −0.09% | −0.12% | −0.20% | 1.50% | 0.67% | −0.83% |
| −0.08% | −0.12% | −0.14% | 1.86% | 0.75% | −0.92% |
| −0.09% | −0.07% | −0.15% | 2.17% | 0.67% | −0.92% |
| −0.15% | −0.12% | −0.15% | 2.20% | 0.67% | −0.75% |
| −0.08% | −0.12% | −0.08% | 1.50% | 0.50% | −0.50% |
| −0.06% | −0.17% | −0.06% | −1.33% | 0.08% | −0.25% |
| −0.04% | −0.12% | −0.04% | −10.00% | 0.67% | 0.67% |
| −0.08% | −0.07% | 0.08% | −48.00% | 1.83% | 1.75% |
| −0.06% | −0.07% | 0.02% | 100.00% | 2.08% | 1.92% |
| −0.25% | −0.07% | 0.00% | — | 0.17% | −0.25% |
| −0.18% | −0.12% | 0.00% | — | 0.18% | −0.25% |
| −0.20% | −0.10% | 0.00% | — | 0.20% | −0.25% |
| −0.25% | −0.09% | 0.00% | — | 0.25% | −0.25% |
| −0.33% | −0.15% | 0.00% | — | 0.17% | −0.25% |
| −0.25% | −0.15% | 0.00% | — | 2.00% | −0.83% |
| −1.00% | −0.19% | 0.00% | — | 4.50% | −0.83% |
| −1.00% | −0.24% | 0.00% | — | 6.00% | −0.67% |
| — | −0.33% | 0.00% | — | — | −0.83% |

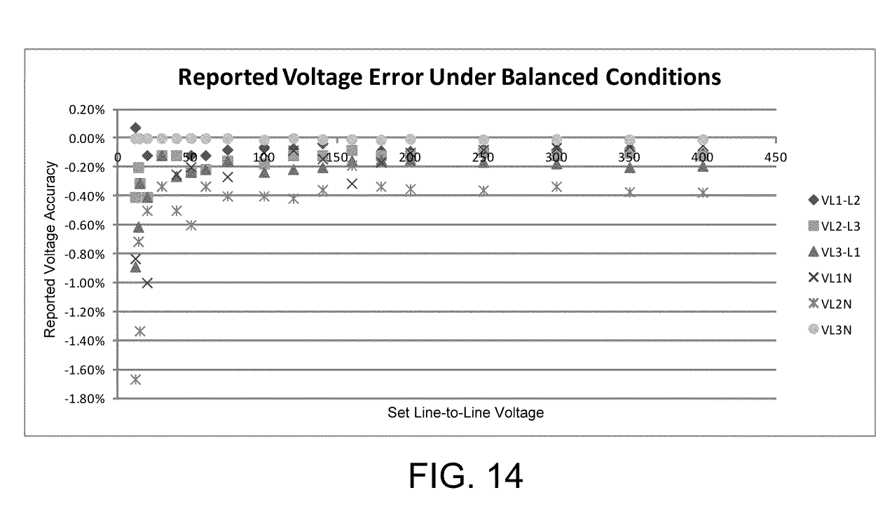

FIG. 14 is a plot of laboratory test results showing reported voltage error under balanced conditions using the first geometric method. The apparatus and three-phase power system used for the results shown in FIG. 13 were again used for testing. In this particular test, line-to-neutral voltages were varied from zero to 400 volts and the voltage on each phase was the same as for the other phases so that the voltages remained balanced. The measured voltages were compared to the calculated voltages. Table 3 and Table 4 show the test results used for FIG. 14. In Table 3, the first three columns are the set line-to-neutral voltages of the test equipment. The next three columns show expected line-to-line voltages, and the next three columns show reported line-to-line voltages from the metering device. The next three columns indicate reported line-to-neutral voltages that were calculated by the metering device using and embodiment of the apparatus 200 and methods 800, 1200 described above. The last three columns show measured output voltage of the test equipment using a separate reference metering device. Table 4 includes calculated error for line-to-line voltages and line-to-neutral voltages. The results of Table 4 are included in FIG. 14. Note that the error was greatest near zero, but under most conditions the error was very low. Test results reveal that the voltage measurement apparatus 102 may be a viable method for determining line-to-neutral voltages where a neutral or ground is unavailable.

TABLE 2

| Set L-N Volt. | | | Expected L-L V | | | Reported L-L V | | | Reported L-N V | | | CA L-N V | | |
|---|---|---|---|---|---|---|---|---|---|---|---|---|---|---|
| L1N | L2N | L3N | L12 | L23 | L31 | L12 | L23 | L31 | L1N | L2N | L3N | L1N | L2N | L3N |
| 0 | 0 | 0 | 0 | 0 | 0 | 0 | 0 | 0 | 0 | 0 | 0 | 0 | 0 | 0 |
| 5 | 5 | 5 | 9 | 9 | 9 | 0 | 0 | 0 | 0 | 0 | 0 | 5 | 5 | 5 |
| 10 | 10 | 10 | 17 | 17 | 17 | 0 | 0 | 0 | 0 | 0 | 0 | 10 | 10 | 10 |
| 12 | 12 | 12 | 21 | 21 | 21 | 21 | 21 | 21 | 12 | 12 | 12 | 12 | 12 | 12 |
| 14 | 14 | 14 | 24 | 24 | 24 | 24 | 24 | 24 | 14 | 14 | 14 | 14 | 14 | 14 |
| 15 | 15 | 15 | 26 | 26 | 26 | 26 | 26 | 26 | 15 | 15 | 15 | 15 | 15 | 15 |
| 20 | 20 | 20 | 35 | 35 | 35 | 35 | 35 | 35 | 20 | 20 | 20 | 20 | 20 | 20 |
| 30 | 30 | 30 | 52 | 52 | 52 | 52 | 52 | 52 | 30 | 30 | 30 | 30 | 30 | 30 |
| 40 | 40 | 40 | 69 | 69 | 69 | 69 | 69 | 69 | 40 | 40 | 40 | 40 | 40 | 40 |
| 50 | 50 | 50 | 87 | 87 | 87 | 87 | 86 | 86 | 50 | 50 | 50 | 50 | 50 | 50 |
| 60 | 60 | 60 | 104 | 104 | 104 | 104 | 104 | 104 | 60 | 60 | 60 | 60 | 60 | 60 |
| 75 | 75 | 75 | 130 | 130 | 130 | 130 | 130 | 130 | 75 | 75 | 75 | 75 | 75 | 75 |
| 100 | 100 | 100 | 173 | 173 | 173 | 173 | 173 | 173 | 100 | 100 | 100 | 100 | 100 | 100 |

TABLE 3

| Set L-N Volt. | | | Expected L-L V | | | Reported L-L V | | | Reported L-N V | | | CA L-N V | | |
|---|---|---|---|---|---|---|---|---|---|---|---|---|---|---|
| L1N | L2N | L3N | L12 | L23 | L31 | L12 | L23 | L31 | L1N | L2N | L3N | L1N | L2N | L3N |
| 120 | 120 | 120 | 208 | 208 | 208 | 208 | 208 | 207 | 120 | 120 | 120 | 120 | 120 | 120 |
| 140 | 140 | 140 | 242 | 242 | 242 | 242 | 242 | 242 | 140 | 140 | 140 | 140 | 140 | 140 |
| 160 | 160 | 160 | 277 | 277 | 277 | 277 | 277 | 277 | 160 | 160 | 160 | 160 | 160 | 160 |
| 180 | 180 | 180 | 312 | 312 | 312 | 312 | 311 | 311 | 180 | 180 | 179 | 180 | 180 | 180 |
| 200 | 200 | 200 | 346 | 346 | 346 | 346 | 346 | 346 | 200 | 200 | 199 | 200 | 200 | 200 |
| 250 | 250 | 250 | 433 | 433 | 433 | 433 | 433 | 432 | 250 | 250 | 249 | 250 | 250 | 250 |
| 300 | 300 | 300 | 520 | 520 | 520 | 519 | 519 | 519 | 300 | 300 | 299 | 300 | 300 | 300 |
| 350 | 350 | 350 | 606 | 606 | 606 | 606 | 606 | 605 | 349 | 350 | 349 | 350 | 350 | 350 |
| 400 | 400 | 400 | 693 | 693 | 693 | 692 | 692 | 692 | 400 | 400 | 399 | 400 | 400 | 400 |

| | L-to-L Error | | | L-to-N Error | | |
|---|---|---|---|---|---|---|
| Set VLN | VL1-L2 | VL2-L3 | VL3-L1 | VL1N | VL2N | VL3N |
| 0 | #DIV/0! | #DIV/0! | #DIV/0! | #DIV/0! | #DIV/0! | #DIV/0! |
| 5 | 100.00% | 100.00% | 100.00% | 100.00% | 100.00% | 0.00% |
| 10 | 100.00% | 100.00% | 100.00% | 100.00% | 100.00% | 0.00% |
| 12 | 0.07% | −0.41% | −0.89% | −0.83% | −1.67% | 0.00% |
| 14 | −0.20% | −0.20% | −0.61% | −0.71% | −0.71% | 0.00% |
| 15 | −0.31% | −0.31% | −0.31% | −1.33% | −1.33% | 0.00% |
| 20 | −0.12% | −0.41% | −0.41% | −1.00% | −0.50% | 0.00% |
| 30 | −0.12% | −0.12% | −0.12% | −0.33% | −0.33% | 0.00% |
| 40 | −0.12% | −0.12% | −0.26% | −0.25% | −0.50% | 0.00% |
| 50 | −0.12% | −0.23% | −0.23% | −0.20% | −0.60% | 0.00% |
| 60 | −0.12% | −0.21% | −0.21% | −0.33% | −0.33% | 0.00% |
| 75 | −0.08% | −0.16% | −0.16% | −0.27% | −0.40% | 0.00% |
| 100 | −0.06% | −0.18% | −0.23% | −0.10% | −0.40% | −0.01% |
| 120 | −0.07% | −0.12% | −0.21% | −0.08% | −0.42% | 0.00% |
| 140 | −0.04% | −0.12% | −0.20% | −0.14% | −0.36% | −0.01% |
| 160 | −0.08% | −0.08% | −0.15% | −0.31% | −0.19% | −0.01% |
| 180 | −0.09% | −0.12% | −0.15% | −0.17% | −0.33% | −0.01% |
| 200 | −0.09% | −0.12% | −0.15% | −0.10% | −0.35% | 0.00% |
| 250 | −0.07% | −0.10% | −0.16% | −0.08% | −0.36% | −0.01% |
| 300 | −0.08% | −0.12% | −0.18% | −0.07% | −0.33% | −0.01% |
| 350 | −0.07% | −0.10% | −0.20% | −0.06% | −0.37% | −0.01% |
| 400 | −0.10% | −0.12% | −0.19% | −0.05% | −0.38% | −0.01% |

The described examples and embodiments are to be considered in all respects only as illustrative and not restrictive. This written description uses examples and embodiments to disclose the invention, including best mode, and also to enable any person skilled in the art to practice the invention, including making and using any devices or systems and performing any incorporated methods. The examples and embodiments may be practiced in other specific forms. The patentable scope of this invention is defined by the claims and may include other examples that occur to those skilled in the art. Such other examples are intended to be within the claims if they have structural elements that do not differ from the literal language of the claims, or if they include equivalent structural element with insubstantial differences from the literal languages of the claims.

What is claimed is:

1. A method for determining voltage, the method comprising:
measuring three line-to-line voltages for the phases in a three-phase power system, each line-to-line voltage comprising a voltage magnitude;
constructing, on a two-dimensional coordinate system with an origin, a phasor triangle comprising the three line-to-line voltages represented as phasors, wherein a first phasor V_{ab} originates at a first point and extends in a direction along a horizontal axis of the coordinate system to the origin, a second phasor V_{bc} extends between the origin and a second point, the second point in a direction vertically and horizontally from the origin, and a third phasor V_{ca} extends between the second point and the first point;
adding a first line segment that extends from a point that bisects the second phasor V_{bc} in a direction perpendicular to the second phasor V_{bc} and away from the phasor triangle, the first line segment terminating at a third point;
adding a second line segment that extends from a point that bisects the third phasor V_{ca} in a direction perpendicular to the third phasor V_{ca} and away from the phasor triangle, the second line segment terminating at a fourth point;
adding a third line segment from the third point to the first point;
adding a fourth line segment from the fourth point to the origin, wherein the third line segment intersects the fourth line segment at a neutral point; and
determining a line-to-neutral voltage, the line-to-neutral voltage comprising a line from the neutral point to a vertex of the phasor triangle.

2. The method of claim 1, wherein determining a line-to-neutral voltage comprises one or more of:
determining a line-to-neutral voltage for a phasor Vₐₙ for phase A which comprises determining a line from the neutral point to the first point;
determining a line-to-neutral voltage for a phasor V_{bn} for phase B which comprises determining a line from the neutral point to the origin; and
determining a line-to-neutral voltage for a phasor V_{cn} for phase C which comprises determining a line from the neutral point to the second point.

3. The method of claim 2, further comprising one or more of:
determining a magnitude of phasor Vₐₙ as
Vₐₙ=\sqrt{(xₐ−xₙ)²+(yₐ−yₙ)²};
determining a magnitude of phasor V_{bn} as
V_{bn}=\sqrt{(x_{b}−xₙ)²+(y_{b}−yₙ)²}; and
determining a magnitude of phasor V_{cn} as
V_{cn}=\sqrt{(x_{c}−xₙ)²+(y_{c}−yₙ)²}.

4. The method of claim 1, wherein the first point comprises a coordinate of (xₐ, yₐ), the second point comprises a coordinate of (x_{c}, y_{c}), and the origin comprises a coordinate of (x_{b}, y_{b}) wherein:
xₐ=the magnitude of the V_{ab} phasor and yₐ=0;
x_{b}=0 and y_{b}=0; and
$${x}_{c} = \frac{{V}_{ab}^{2} - {V}_{ca}^{2} + {V}_{bc}^{2}}{2 \cdot {V}_{ab}} and {y}_{c} = {V}_{ca} \cdot \sqrt{1 - ( \frac{{V}_{bc}^{2} - {V}_{ab}^{2} - {V}_{ca}^{2}}{4 \cdot {V}_{ab}^{2} \cdot {V}_{ca}^{2}} )} ,$$
where V_{ab} is a magnitude of the first phasor V_{ab}, V_{bc} is a magnitude of the second phasor V_{bc}, and V_{ca} is a magnitude of the third phasor V_{ca}.

5. The method of claim 1, wherein the length of the first line segment comprises a magnitude of the third phasor V_{ca} divided by the square root of three and multiplied by the square root of one plus the square of the slope of the first line segment and wherein the length of the second line segment comprises a magnitude of the second phasor V_{bc} divided by the square root of three and multiplied by the square root of one plus the square of the slope of the second line segment.

6. The method of claim 5, wherein the length of the first line segment comprises
$$\frac{{V}_{ca}}{\sqrt{3}} \cdot \sqrt{1 + {( \frac{- {x}_{c}}{{y}_{c}} )}^{2}}$$
and wherein the length of the second line segment comprises
$$\frac{{V}_{bc}}{\sqrt{3}} \cdot \sqrt{1 + {( \frac{- ( {x}_{a} - {x}_{c} )}{( {y}_{a} - {y}_{c} )} )}^{2}} .$$

7. The method of claim 5, wherein the third point comprises a coordinate of (x_{pbc}, y_{pbc}) and the fourth point comprises a coordinate of (x_{pca}, y_{pca}), wherein
$${x}_{pbc} = \frac{{x}_{c}}{2} - \frac{{V}_{ca}}{\sqrt{3}} ;$$
$${y}_{pbc} = \frac{{y}_{c}}{2} - \frac{- {x}_{c}}{{y}_{c}} \cdot \frac{{V}_{ca}}{\sqrt{3}} ;$$
$${x}_{pca} = {x}_{c} + \frac{{x}_{a} - {x}_{c}}{2} + \frac{{V}_{bc}}{\sqrt{3}} ; and$$
$${y}_{pca} = \frac{{y}_{c}}{2} + \frac{- ( {x}_{a} - {x}_{c} )}{( {y}_{a} - {y}_{c} )} \cdot \frac{{V}_{bc}}{\sqrt{3}} .$$

8. The method of claim 7, wherein the neutral point comprises a coordinate of (xₙ, yₙ) and wherein:
$${x}_{n} = \frac{\frac{{y}_{pbc}}{{x}_{a} - {x}_{pbc}} \cdot {x}_{a}}{\frac{{y}_{pca}}{{x}_{pca}} + \frac{{y}_{pbc}}{{x}_{a} - {x}_{pbc}}} ; and$$
$${y}_{n} = \frac{{y}_{pca}}{{x}_{pca}} \cdot {x}_{n} .$$

9. The method of claim 8, wherein where yₙ is less than zero then yₙ=0, and where yₙ is greater than or equal to zero and greater than y_{c} then yₙ=y_{c}.

10. The method of claim 9, wherein where xₙ is less than zero then xₙ=0, and where xₙ is greater than or equal to zero and greater than xₐ then xₙ=xₐ, and where xₙ is greater than or equal to zero and less than or equal to xₐ and y_{c}=y, then xₙ=x_{c}.

11. The method of claim 1, wherein the length of the first line segment has a magnitude of the second phasor V_{bc} multiplied by the square root of three and divided by two, which represents a height of a first equilateral triangle constructed on the second phasor V_{bc} and extending away from the phasor triangle and wherein the length of the second line segment has a magnitude of the third phasor V_{ca} multiplied by the square root of three and divided by two, which represents a height of a second equilateral triangle constructed on the third phasor V_{ca} and extending away from the phasor triangle.

12. The method of claim 11, wherein the third point comprises a coordinate of (x_{pbc}, y_{pbc}) and the fourth point comprises a coordinate of (x_{pca}, y_{pca}), wherein
$${x}_{pbc} = \frac{{x}_{c} - {y}_{c} \cdot \sqrt{3}}{2} ;$$
$${y}_{pbc} = \frac{{y}_{c} + {x}_{c} \cdot \sqrt{3}}{2} ;$$
$${x}_{pca} = {x}_{a} + \frac{{x}_{c} - {x}_{a} + \sqrt{3} \cdot {y}_{c}}{2} ; and$$
$${y}_{pca} = \frac{( {y}_{c} - {y}_{a} ) + \sqrt{3} \cdot ( {x}_{a} - {x}_{c} )}{2} .$$

13. The method of claim 12, wherein the neutral point comprises a coordinate of (xₙ, yₙ) and wherein:
$${x}_{n} = \frac{\frac{{x}_{a} \cdot {y}_{pbc}}{{x}_{a} - {x}_{pbc}}}{\frac{{y}_{pca}}{{x}_{pca}} + \frac{{y}_{pbc}}{{x}_{a} - {x}_{pbc}}} ; and$$
$${y}_{n} = \frac{{y}_{pca}}{{x}_{pca}} \cdot {x}_{n} .$$

14. The method of claim 1, wherein the line-to-line voltages are measured at a location in the three-phase power system where a neutral connection is unavailable for measurement.

15. The method of claim 1, wherein the three-phase power system comprises an ungrounded power system.

16. The method of claim 1, wherein the three-phase power system comprises unbalanced voltages.

17. The method of claim 1, wherein the first phasor V_{ab}, the second phasor V_{bc}, and the third phasor V_{ca} are separated by 120 degrees.

18. An apparatus comprising:
a measurement module that measures three line-to-line voltages for the phases in a three-phase power system, each line-to-line voltage comprising a voltage magnitude;
a triangle module that constructs, on a two-dimensional coordinate system with an origin, a phasor triangle comprising the three line-to-line voltages represented as phasors, wherein a first phasor V_{ab} originates at a first point and extends in a direction along a horizontal axis of the coordinate system to the origin, a second phasor V_{bc} extends between the origin and a second point, the second point in a direction vertically and horizontally from the origin, and a third phasor V_{ca} extends between the second point and the first point;
a first line module that adds a first line segment that extends from a point that bisects the second phasor V_{bc} in a direction perpendicular to the second phasor V_{bc} and away from the phasor triangle, the first line segment terminating at a third point;
a second line module that adds a second line segment that extends from a point that bisects the third phasor V_{ca} in a direction perpendicular to the third phasor V_{ca} and away from the phasor triangle, the second line segment terminating at a fourth point;
a third line module that adds a third line segment from the third point to the first point;
a fourth line module that adds a fourth line segment from the fourth point to the origin, wherein the third line segment intersects the fourth line segment at a neutral point; and
a line-to-neutral module that determines a line-to-neutral voltage, the line to-neutral voltage comprising a line from the neutral point to a vertex of the phasor triangle,
wherein at least a portion of said modules comprise one or more of hardware and executable code, the executable code stored on one or more computer readable storage media.

19. The apparatus of claim 18, wherein the line-to-neutral module determines a line-to-neutral voltage by:
determining a line-to-neutral voltage for phasor Vₐₙ for phase A which comprises determining a line from the neutral point to the first point;
determining a line-to-neutral voltage for phasor V_{bn} for phase B which comprises determining a line from the neutral point to the origin; and
determining a line-to-neutral voltage for phasor V_{cn} for phase C which comprises determining a line from the neutral point to the second point.

20. The apparatus of claim 19, further comprising a line-to-neutral magnitude module that one or more of:
determines a magnitude of phasor Vₐₙ as
Vₐₙ=\sqrt{(xₐ−xₙ)²+(yₐ−yₙ)²},
determines a magnitude of phasor V_{bn} as
V_{bn}=\sqrt{(x_{b}−xₙ)²+(y_{b}−yₙ)²}, and
determines a magnitude of phasor V_{cn} as
V_{cn}=\sqrt{(x_{c}−xₙ)²+(y_{c}−yₙ)²}.

21. The apparatus of claim 18, wherein first point comprises a coordinate of (xₐ, yₐ), the second point comprises a coordinate of (x_{c}, y_{c}), and the origin comprises a coordinate of (x_{b}, y_{b}) wherein:
xₐ=the magnitude of the V_{ab} phasor and yₐ=0;
x_{b}=0 and y_{b}=0; and
$${x}_{c} = \frac{{V}_{ab}^{2} - {V}_{ca}^{2} + {V}_{bc}^{2}}{2 \cdot {V}_{ab}} and {y}_{c} = {V}_{ca} \cdot \sqrt{1 - ( \frac{{V}_{bc}^{2} - {V}_{ab}^{2} - {V}_{ca}^{2}}{4 \cdot {V}_{ab}^{2} \cdot {V}_{ca}^{2}} )} ,$$
where V_{ab} is a magnitude of the first phasor V_{ab}, V_{bc} is a magnitude of the second phasor V_{bc}, and V_{ca} is a magnitude of the third phasor V_{ca}.

22. The apparatus of claim 21, wherein the length of the first line segment comprises a magnitude of the third phasor V_{ca} divided by the square root of three and multiplied by the square root of one plus the square of the slope of the first line segment and wherein the length of the second line segment comprises a magnitude of the second phasor V_{bc} divided by the square root of three and multiplied by the square root of one plus the square of the slope of the second line segment.

23. The apparatus of claim 21, wherein the third point comprises a coordinate of (x_{pbc}, y_{pbc}) and the fourth point comprises a coordinate of (x_{pca}, y_{pca}), wherein
$${x}_{pbc} = \frac{{x}_{c}}{2} - \frac{{V}_{ca}}{\sqrt{3}} ;$$
$${y}_{pbc} = \frac{{y}_{c}}{2} - \frac{- {x}_{c}}{{y}_{c}} \cdot \frac{{V}_{ca}}{\sqrt{3}} ;$$
$${x}_{pca} = {x}_{c} + \frac{{x}_{a} - {x}_{c}}{2} + \frac{{V}_{bc}}{\sqrt{3}} ; and$$
$${y}_{pca} = \frac{{y}_{c}}{2} + \frac{- ( {x}_{a} - {x}_{c} )}{( {y}_{a} - {y}_{c} )} \cdot \frac{{V}_{bc}}{\sqrt{3}} .$$

24. The apparatus of claim 23, wherein the neutral point comprises a coordinate of (xₙ, yₙ) and wherein:
$${x}_{n} = \frac{\frac{{y}_{pbc}}{{x}_{a} - {x}_{pbc}} \cdot {x}_{a}}{\frac{{y}_{pca}}{{x}_{pca}} + \frac{{y}_{pbc}}{{x}_{a} - {x}_{pbc}}} ; and$$
$${y}_{n} = \frac{{y}_{pca}}{{x}_{pca}} \cdot {x}_{n} .$$

25. The apparatus of claim 24, wherein where yₙ is less than zero then yₙ=0, and where yₙ is greater than or equal to zero and greater than y_{c} then yₙ=y_{c}.

26. The apparatus of claim 25, wherein where xₙ is less than zero then xₙ=0, and where xₙ is greater than or equal to zero and greater than xₐ then xₙ=xₐ, and where xₙ is greater than or equal to zero and less than or equal to xₐ and y_{c}=yₙ then xₙ=x_{c}.

27. The apparatus of claim 18, wherein the length of the first line segment has a magnitude of the second phasor V_{bc} multiplied by the square root of three and divided by two, which represents a height of a first equilateral triangle constructed on the second phasor V_{bc} and extending away from the phasor triangle and wherein the length of the second line segment has a magnitude of the third phasor V_{ca} multiplied by the square root of three and divided by two, which represents a height of a second equilateral triangle constructed on the third phasor V_{ca} and extending away from the phasor triangle.

28. The apparatus of claim 27, wherein the third point comprises a coordinate of (x_{pbc}, y_{pbc}) and the fourth point comprises a coordinate of (x_{pca}, y_{pca}) and wherein
$${x}_{pbc} = \frac{{x}_{c} - {y}_{c} \cdot \sqrt{3}}{2} ;$$
$${y}_{pbc} = \frac{{y}_{c} + {x}_{c} \cdot \sqrt{3}}{2} ;$$
$${x}_{pca} = {x}_{a} + \frac{{x}_{c} - {x}_{a} + \sqrt{3} \cdot {y}_{c}}{2} ; and$$
$${y}_{pca} = \frac{( {y}_{c} - {y}_{a} ) + \sqrt{3} \cdot ( {x}_{a} - {x}_{c} )}{2} .$$

29. The apparatus of claim 28, wherein the neutral point comprises a coordinate of (xₙ, yₙ) and wherein:
$${x}_{n} = \frac{\frac{{x}_{a} \cdot {y}_{pbc}}{{x}_{a} - {x}_{pbc}}}{\frac{{y}_{pca}}{{x}_{pca}} + \frac{{y}_{pbc}}{{x}_{a} - {x}_{pbc}}} ; and$$
$${y}_{n} = \frac{{y}_{pca}}{{x}_{pca}} \cdot {x}_{n} .$$

30. The apparatus of claim 18, further comprising a meter, the meter comprising the measurement module.

31. The apparatus of claim 18, further comprising a processor, the processor executing executable code of one or more of the measurement module, the triangle module, the first line module, the second line module, the third line module, the fourth line module, and the line-to-neutral module.

32. A computer program product for determining a voltage, the computer program product comprising a computer readable storage medium having program code embodied therein, the program code readable/executable by a processor for:
measuring three line-to-line voltages for the phases in a three-phase power system, each line-to-line voltage comprising a voltage magnitude;
constructing, on a two-dimensional coordinate system with an origin, a phasor triangle comprising the three line-to-line voltages represented as phasors, wherein a first phasor V_{ab} originates at a first point and extends in a direction along a horizontal axis of the coordinate system to the origin, a second phasor V_{bc} extends between the origin and a second point, the second point in a direction vertically and horizontally from the origin, and a third phasor V_{ca} extends between the second point and the first point;
determining a third point by adding a first line segment that extends from a point that bisects the second phasor V_{bc} in a direction perpendicular to the second phasor V_{bc} and away from the phasor triangle, the first line segment terminating at the third point;
determining a fourth point by adding a second line segment that extends from a point that bisects the third phasor V_{ca} in a direction perpendicular to the third phasor V_{ca} and away from the phasor triangle, the second line segment terminating at the fourth point;
determining a neutral point by adding a third line segment from the third point to the first point and adding a fourth line segment from the fourth point to the origin, wherein the third line segment intersects the fourth line segment at the neutral point; and
determining a line-to-neutral voltage, the line-to-neutral voltage comprising a line from the neutral point to a vertex of the phasor triangle.
